(19) United States
(12) Patent Application Publication
(10) Pub. No.: US 2024/0404846 A1
(43) Pub. Date: Dec. 5, 2024

(54) SUBSTRATE PROCESSING APPARATUS

(71) Applicant: SCREEN Holdings Co., Ltd., Kyoto (JP)

(72) Inventor: Shuhei NEMOTO, Kyoto (JP)

(21) Appl. No.: 18/674,813

(22) Filed: May 24, 2024

(30) Foreign Application Priority Data
May 30, 2023 (JP) 2023-088809
Aug. 29, 2023 (JP) 2023-138809
Aug. 29, 2023 (JP) 2023-138810

(51) Int. Cl. H01L 21/67; H01L 21/68

(52) U.S. Cl. CPC H01L 21/6708; H01L 21/68

(57) ABSTRACT

In a substrate processing apparatus, a rotating mechanism holds a circular substrate in a horizontal posture and rotates the substrate about a vertical axis passing through a center of the substrate. A nozzle mechanism includes a nozzle body, a support and a position adjuster. The nozzle body is arranged below the substrate and having a discharge port from which a processing liquid is discharged toward a lower surface peripheral edge part of the substrate. The support supports the nozzle body in a manner that makes the position of the discharge port changeable in a radial direction of the substrate. The position adjuster adjusts the position of the discharge port by moving the nozzle body relative to the support. Thee support and the position adjuster are arranged internal to a virtual arc centered on the vertical axis and passing through the discharge port.

### CROSS REFERENCE TO RELATED APPLICATION

The disclosure of Japanese Patent Applications enumerated below including specifications, drawings and claims is incorporated herein by reference in its entirety:

No. 2023-088809 filed on May 30, 2023;

No. 2023-138809 filed on Aug. 29, 2023; and

No. 2023-138810 filed on Aug. 29, 2023.

### BACKGROUND OF THE INVENTION

### 1. Field of the Invention

The present invention relates to a substrate processing apparatus that processes a peripheral edge part of a substrate by supplying a processing liquid to the peripheral edge part in an internal space of a chamber.

### 2. Description of the Related Art

There is an existing process on a circular or substantially circular substrate such as a semiconductor wafer for removing only a thin film on a peripheral edge part of the substrate that is a part of a thin film formed on at least one principal surface of the substrate.

According to a known technique, an etching liquid is supplied to a peripheral edge part of a substrate while the substrate is rotated to remove only a thin film external to a position of supply with the etching liquid, for example. In some cases, such a process of removing the thin film in this way is called a bevel etching process.

Referring to Japanese Patent Application Laid-Open No. 2022-052835, for example, in a substrate processing apparatus housed in a processing chamber, a lower peripheral edge nozzle is provided below a substrate for implementation of an etching process on a peripheral edge part of a lower surface of the substrate in a horizontal posture. The lower peripheral edge nozzle has a nozzle support member mounted with a plurality of nozzles. Each of the nozzles discharges a processing liquid such as a chemical liquid or a rinsing liquid upward toward the peripheral edge part of the lower surface of the substrate.

### SUMMARY OF INVENTION

For implementation of this process, the width of a region of the thin film where the thin film is to be removed (etching width) is required to be adjusted to a preset target value. Thus, in the substrate processing apparatus after assembly or before start of use of the apparatus after component replacement, it becomes necessary to perform an adjusting operation in order to obtain a predetermined etching width. Meanwhile, a constant etching width is not always required in the process but an etching width may be changed according to a purpose. The above-described conventional technique does not disclose particulars of a structure of mounting the nozzle on the nozzle support member, so that it does not provide a way of making the adjustment.

For a purpose such as size reduction of a device or improvement of a yield, accuracy required for the adjustment of the etching width is being increased particularly in recent years. For example, the adjustment is required to be made on the order of several tens of microns. A mechanism applicable for achieving such an adjustment has yet to be established.

In a substrate processing system of this type, processing chambers housing substrate processing units are stacked in tiers in many cases for improving a footprint. Furthermore, for reducing the usage of gas in each processing chamber to encourage reduction in environmental load, it is required to control the size of each processing chamber in terms of a planar size viewed from vertically above or a height, for example. For this reason, the above-described nozzle and a mechanism for adjusting the position of the nozzle are desirably as compact as possible.

The present invention has been made in view of the foregoing problems. In a substrate processing apparatus where a nozzle is arranged below a substrate, the present invention is intended to provide a mechanism allowing position adjustment of the nozzle with high accuracy and having a configuration available for encouraging reduction in environmental load.

One aspect of this invention is directed to a substrate processing apparatus. The apparatus comprises: a rotating mechanism configured to hold a circular substrate in a horizontal posture and rotates the substrate about a vertical axis passing through a center of the substrate; and a nozzle mechanism including a nozzle body, a support and a position adjuster, the nozzle body being arranged below the substrate and having a discharge port from which a processing liquid is discharged toward a lower surface peripheral edge part of the substrate, the support being configured to support the nozzle body in a manner that makes the position of the discharge port changeable in a radial direction of the substrate, the position adjuster being configured to adjust the position of the discharge port by moving the nozzle body relative to the support, wherein the support and the position adjuster are arranged internal to a virtual arc centered on the vertical axis and passing through the discharge port.

According to the invention having the above-described configuration, the nozzle body is supported by the support in such a manner as to make the position of the discharge port changeable in the radial direction of the substrate. The position adjuster moves the nozzle body relative to the support. In response to this movement of the nozzle body, the position of the discharge port is adjusted. This causes the processing liquid discharged from the discharge port to land on the substrate at a different liquid landing position, thereby adjusting an etching width. Furthermore, the nozzle body and the position adjuster are arranged internal to the virtual arc centered on the vertical axis and passing through the discharge port, and are always arranged internal to the discharge port in the radial direction in a plan view vertically from above. As a result, it also becomes possible to adjust an etching width with high accuracy at the peripheral edge part of the substrate yet using the compact configuration. This contributes to reduction in the usage of gas in the substrate processing apparatus to allow reduction in environmental load.

The processing liquid supplied to the lower surface peripheral edge part of the substrate is scattered in the radial direction. At this time, if all or some of the nozzle body and the position adjuster are present external to the discharge port in the radial direction, these structures may disperse the processing liquid scattered from the lower surface peripheral edge part and may move the processing liquid back to the substrate. By contrast, in the substrate processing apparatus having the foregoing configuration, the nozzle body and the position adjuster are always present internal to the discharge port, thereby preventing this problem reliably.

In the above-described invention, the “circular substrate” is a concept covering not only a substrate having a principal surface of a circular shape in a strict sense in a plan view but also a “substantially circular substrate” having a circular enveloping outer shape while having an outer periphery different from a circumference for the presence of a part such as an orientation flat or a cutout formed in a partial area of the outer periphery.

According to the present invention, in the substrate processing apparatus where the nozzle is arranged below the substrate, it is possible to adjust the position of the nozzle with high accuracy yet using the compact configuration.

All of a plurality of constituent elements of each aspect of the present invention described above are not essential and some of the plurality of constituent elements can be appropriately changed, deleted, replaced by other new constituent elements or have limited contents partially deleted in order to solve some or all of the aforementioned problems or to achieve some or all of effects described in this specification. Further, some or all of technical features included in one aspect of the present invention described above can be combined with some or all of technical features included in another aspect of the present invention described above to obtain one independent form of the present invention in order to solve some or all of the aforementioned problems or to achieve some or all of the effects described in this specification.

### BRIEF DESCRIPTION OF THE DRAWINGS

FIG. 1 is a plan view showing a schematic configuration of a substrate processing system equipped with an embodiment of a substrate processing apparatus according to the present invention.

FIGS. 2 and 3 show the configuration of a principal part of the substrate processing apparatus according to the present invention.

FIG. 4 shows a state where the upper cup is a moved-up position.

FIG. 5 shows the configuration and layout of the processing mechanism.

FIG. 6 is an exploded perspective view showing the configuration of one processing liquid discharge nozzle.

FIGS. 7A, 7B and 7C show a sectional configuration of this processing liquid discharge nozzle.

FIG. 8 explains the action of nozzle position adjustment fulfilled by the processing mechanism.

FIGS. 9A and 9B show a positional relationship viewed from vertically above between the discharge port, the base member, the male screw part, the coil spring, and the adjusting nut.

FIGS. 10A and 10B show the configuration of the substrate observing mechanism.

FIG. 11 schematically shows the nozzle position adjustment in the fine adjusting mode.

FIG. 12 shows a modification of the nozzle block.

FIG. 13 shows the configuration and layout of a processing mechanism provided in an automatic adjustment type substrate processing apparatus corresponding to an example of a different embodiment of the substrate processing apparatus according to the present invention.

FIGS. 14A, 14B, 15A, and 15B show the configurations of the processing liquid discharge nozzle and the nozzle moving mechanism.

FIG. 16 is an exploded assembly view showing a method of fitting the glide rings in a pair to the fixed support.

FIG. 17 shows the configuration of the glide ring.

FIG. 18 schematically shows nozzle position adjustment in the automatic adjusting mode.

FIG. 19 schematically shows the configuration and motion of a nozzle mover.

FIG. 20 shows the configuration and layout of a processing mechanism provided in an automatic adjustment type substrate processing apparatus corresponding to an example of a different embodiment of the substrate processing apparatus according to the present invention.

FIG. 21 shows the configuration and layout of a processing mechanism provided in an automatic adjustment type substrate processing apparatus corresponding to an example of a still different embodiment of the substrate processing apparatus according to the present invention.

### DETAILED DESCRIPTION OF THE PREFERRED EMBODIMENTS

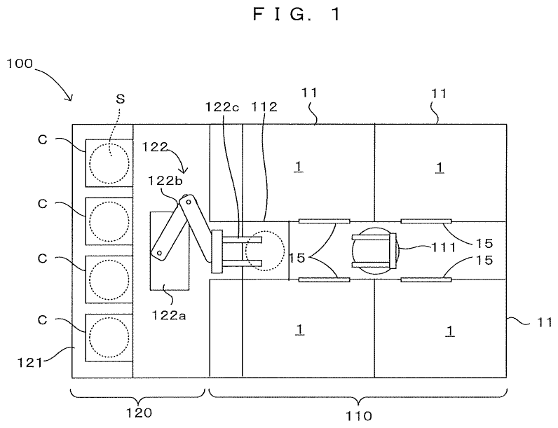

FIG. 1 is a plan view showing a schematic configuration of a substrate processing system equipped with an embodiment of a substrate processing apparatus according to the present invention. This figure is a diagram not showing the external appearance of the apparatus, but showing an internal structure of a substrate processing system 100 by excluding an outer wall panel and other partial configurations. This substrate processing system 100 is, for example, installed in a clean room and processes substrates S one by one. The principal configuration of the substrate processing system 100 shown here is similar to that described in Japanese Patent Application No. 2022-134816 filed by the applicant.

The substrate processing system 100 includes a plurality of processing units (substrate processing apparatuses) 1 each principally responsible for a process on the substrate S. While FIG. 1 shows a state where four processing units 1 are arranged in a horizontal direction, the processing units 1 are also stacked in tiers in a top-bottom direction. If the processing units 1 are stacked in six tiers, for example, the substrate processing system 100 includes 24 processing units 1 in total.

Each of the processing units 1 provided at the substrate processing system 100 performs a substrate process using a processing liquid. In the present specification, a surface belonging to both principal surfaces of a substrate and pointed downward is called a “lower surface” and is given a sign Sb. A surface pointed upward is called a “top surface” and is given a sign St.

Herein, various substrates such as semiconductor wafers, glass substrates for photomask, glass substrates for liquid crystal display, glass substrates for plasma display, substrates for FPD (Flat Panel Display), optical disk substrates, magnetic disk substrates and magneto-optical disk substrates can be applied as the “substrate” in the present embodiment. Although the substrate processing apparatus used in processing semiconductor wafers is mainly described as an example with reference to the drawings below, application to the processing of various substrates illustrated above is also possible.

As will be described later, the processing unit 1 of the present embodiment performs a process of accepting the substrate S with a thin film of metal or a metallic compound formed on one of the principal surfaces, and removing only a peripheral edge part of the thin film formed on the substrate S by an etching process. In some cases, such an etching process is called a “bevel etching process” or simply a “bevel process.” In one configuration, all the processing units 1 provided at the substrate processing system 100 may perform such a bevel etching process. In another configuration, processing units of two or more types to perform different processes may be provided in combination.

As shown in FIG. 1, the substrate processing system 100 includes a substrate processing station 110 for processing the substrate S and an indexer station 120 coupled to this substrate processing station 110. The indexer station 120 includes a container holder 121 capable of holding a plurality of containers C for housing the substrates S (FOUPs (Front Opening Unified Pods), SMIF (Standard Mechanical Interface) pods, OCs (Open Cassettes) for housing a plurality of the substrates S in a sealed state), and an indexer robot 122 for taking out an unprocessed substrate S from the container C by accessing the container C held by the container holder 121 and housing a processed substrate S in the container C. A plurality of the substrates S are housed substantially in a horizontal posture in each container C.

The indexer robot 122 includes a base 122a fixed to apparatus housing, an articulated arm 122b provided rotatably about a vertical axis with respect to the base 122a, and a hand 122c mounted on the tip of the articulated arm 122b. The hand 122c is structured such that the substrate S can be placed and held on the top surface thereof. Such an indexer robot including the articulated arm and the hand for holding the substrate is not described in detail since being known.

The substrate processing station 110 includes a mounting table 112 on which the indexer robot 122 places the substrate S, a substrate conveyor robot 111 arranged substantially in a center in a plan view and a plurality of processing units 1 arranged to surround this substrate conveyor robot 11. Specifically, the plurality of processing units 1 are arranged to face a space where the substrate conveyor robot 111 is arranged. The substrate conveyor robot 111 randomly accesses the mounting table 112 for these processing units 1 and transfers the substrate S to and from the mounting table 112. On the other hand, each processing unit 1 performs a predetermined processing to the substrate S, and corresponds to the substrate processing apparatus according to the present invention.

In the present embodiment, these processing units (substrate processing apparatus) 1 have the same function. Thus, a plurality of the substrates S can be processed in parallel. If the substrate conveyor robot 111 can directly transfer the substrate S from the indexer robot 122, the mounting table 112 is not necessarily required.

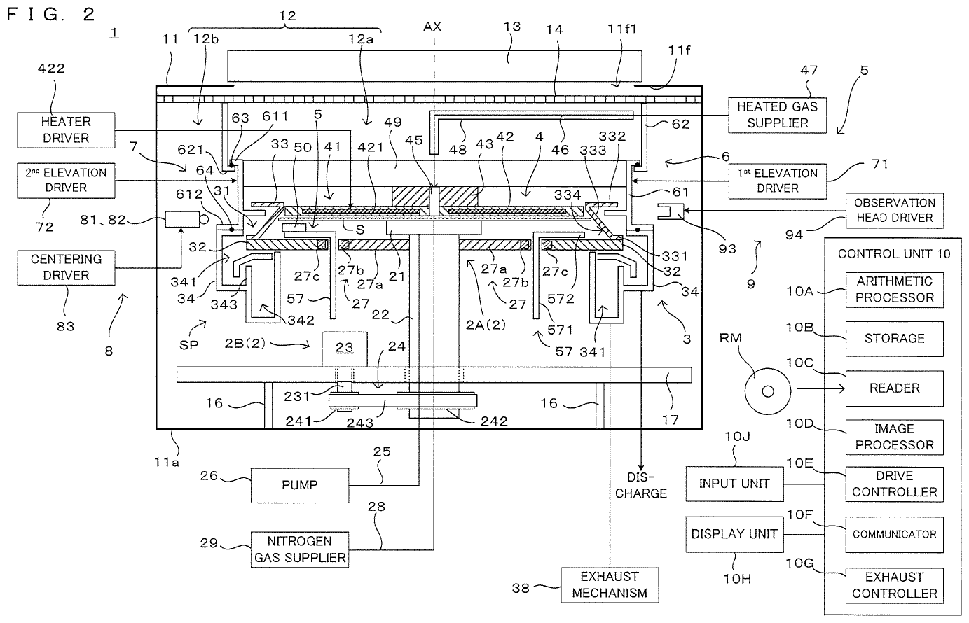

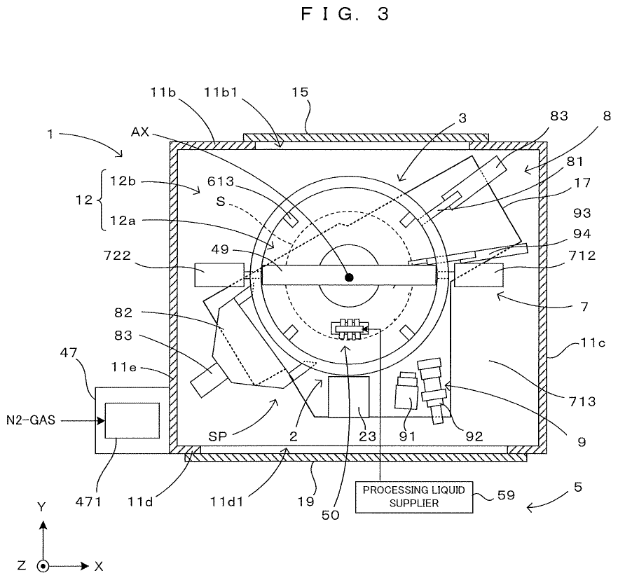

FIGS. 2 and 3 show the configuration of a principal part of the substrate processing apparatus according to the present invention. More specifically, FIG. 2 is a side view and FIG. 3 is a plan view showing an internal configuration of the processing unit 1 as one embodiment of the substrate processing apparatus. In FIGS. 2 and 3 and each of the drawings referred to below, the respective dimensions and numbers of components may be shown in an exaggerated or simplified manner to facilitate understanding. The substrate processing apparatus (processing unit) 1 has a configuration where a substrate processing part SP is arranged in an internal space 12 in a chamber 11.

On a top surface of the bottom wall 11a of the chamber 11, base support members 16 and 16 are fixed away from each other by fastener components such as bolts or the like. Specifically, the base support member 16 stands from the bottom wall 11a. On respective upper end parts of these base support members 16 and 16, a base member 17 is fixed by the fastener components such as bolts or the like. This base member 17 has a plane size smaller than that of the bottom wall 11a and is composed of a plate material having a thickness larger than that of the bottom wall 11a and rigidity higher than that thereof. As shown in FIG. 2, the base member 17 is raised by the base support members 16 and 16 from the bottom wall 11a vertically upward. In other words, a so-called raised floor structure is formed on a bottom part of the internal space 12 of the chamber 11. As described later, a top surface of this base member 17 is finished to allow a substrate processing part SP for performing substrate processing on the substrate S to be installed thereon, and the substrate processing part SP is installed on the top surface thereof. Components constituting this substrate processing part SP are electrically connected to a control unit 10 for controlling the entire apparatus and operate in response to commands from the control unit 10.

As shown in FIG. 2, a fan filter unit (FFU) 13 is attached to a ceiling surface 11f of the chamber 11. This fan filter unit 13 further cleans air in a clean room in which the substrate processing apparatus 1 is installed, and supplies the cleaned air into an internal space 12 of the chamber 11. The fan filter unit 13 includes a fan and a filter (e.g. a HEPA

(High Efficiency Particulate Air) filter) for taking in the air in the clean room and feeding the air into the chamber 11, and feeds the cleaned air via an opening 11f1 provided in the ceiling surface 11f. In this way, a downflow of the cleaned air is formed in the internal space 12 in the chamber 11. Further, a punching plate 14 perforated with a multitude of air outlets is provided right below the ceiling surface 11f to uniformly disperse the cleaned air supplied from the fan filter unit 13.

As shown in FIG. 3, in the substrate processing apparatus 1, a conveyance opening 11b1 is provided in the sidewall 11b facing the substrate conveyor robot 111 among the four sidewalls 11b to 11e, and the internal space 12 communicates with the outside of the chamber 11 therethrough. For this reason, a hand (not shown) of the substrate conveyor robot 111 can access the substrate processing part SP through the conveyance opening 11b1. In other words, by providing the conveyance opening 11b1, the substrate S can be loaded into or unloaded from the internal space 12. Further, a shutter 15 for opening and closing this conveyance opening 11b1 is attached to the sidewall 11b.

A shutter opening/closing mechanism (not shown) is connected to the shutter 15, and opens or closes the shutter 15 in response to an opening/closing command from the control unit 10. More specifically, in the substrate processing apparatus 1, the shutter opening/closing mechanism opens the shutter 15 in carrying an unprocessed substrate S into the chamber 11, and the unprocessed substrate S is carried to the substrate processing part SP of the rotating mechanism 2 by a hand of a substrate conveyor robot 111. If the hand of the substrate conveyor robot 111 is retracted from the chamber 11 after the substrate S is carried into, the shutter opening/closing mechanism closes the shutter 15. Then, a processing is performed on the substrate S by the substrate processing part SP. Further, after the processing is finished, the shutter opening/closing mechanism opens the shutter 15 again and the hand of the substrate conveyor robot 111 carries out the processed substrate S from the substrate processing part SP.

As shown in FIG. 3, the sidewall 11d is positioned on the opposite side of the sidewall 11b with respect to the substrate processing part SP (FIG. 2) installed on the base member 17. In this sidewall 11d, provided is a maintenance opening 11d1. During maintenance, as shown in this figure, the maintenance opening 11d1 is opened. For this reason, an operator can access the substrate processing part SP through the maintenance opening 11d1 from the outside of the apparatus. On the other hand, during the substrate processing, a lid member 19 is so attached as to close the maintenance opening 11d1. Thus, in the present embodiment, the lid member 19 is detachable from the sidewall 11d.

Further, on an outer surface of the sidewall 11e, a heated gas supplier 47 for supplying the substrate processing part SP with a heated inert gas (nitrogen gas in the present embodiment) is attached. The heated gas supplier 47 incorporates a heater 471.

Thus, on the outer wall side of the chamber 11, the shutter 15, the lid member 19, and the heated gas supplier 47 are arranged. In contrast to this, in an inner side of the chamber 11, i.e., in the internal space 12, the substrate processing part SP is installed on the top surface of the base member 17 having the raised floor structure. Hereinafter, the configuration of the substrate processing part SP disposed on the base member 17 will be described.

Hereinafter, for clarifying the arrangement relation and operation of the components of the apparatus, a coordinate system with a Z direction as a vertical direction and with an XY plane as a horizontal plane is shown as appropriate. In the coordinate system of FIG. 3, it is assumed that a horizontal direction corresponding to the vertical direction of the paper surface is an “X direction” and a horizontal direction orthogonal to the X direction is a “Y direction”. Directions vertically upward and downward are referred to as a “+Z direction” and a “-Z direction”, respectively.

As shown in FIGS. 2 and 3, the substrate processing part SP includes a holding/rotating mechanism 2, a scattering preventing mechanism 3, a top surface protecting/heating mechanism 4, a processing mechanism 5, an atmosphere separating mechanism 6, an elevating mechanism 7, a centering mechanism 8, and a substrate observing mechanism 9. These mechanisms are provided on the base member 17. Specifically, with reference to the base member 17 having rigidity higher than that of the chamber 11, the holding/rotating mechanism 2, the scattering preventing mechanism 3, the top surface protecting/heating mechanism 4, the processing mechanism 5, the atmosphere separating mechanism 6, the elevating mechanism 7, the centering mechanism 8, and the substrate observing mechanism 9 are arranged to one another with a positional relation determined in advance.

The holding/rotating mechanism 2 includes a substrate holder 2A for holding the substrate S substantially in a horizontal posture with a film-forming surface of the substrate S facing downward and a rotating mechanism 2B for synchronously rotating the substrate holder 2A holding the substrate S and part of the scattering preventing mechanism 3. For this reason, when the rotating mechanism 2B operates in response to a rotation command from the control unit 10, the substrate S and a rotating cup 31 of the scattering preventing mechanism 3 are rotated about an axis of rotation AX extending in parallel to the vertical direction Z.

The substrate holder 2A includes the spin chuck 21 which is a disk-like member smaller than the substrate S. The spin chuck 21 is so provided that a top surface thereof is substantially horizontal and a center axis thereof coincides with the axis of rotation AX. A cylindrical rotary shaft 22 is coupled to a lower surface of the spin chuck 21. The rotary shaft 22 extends in the vertical direction Z with an axis line thereof coinciding with the axis of rotation AX. Further, the rotating mechanism 2B is connected to the rotary shaft 22.

The rotating mechanism 2B has a motor 23 which generates a rotational driving force for rotating the substrate holder 2A and the rotating cup 31 of the scattering preventing mechanism 3 and a power transmitter 24 for transmitting the rotational driving force. The motor 23 has a rotation shaft 231 rotating with generation of the rotational driving force. The motor 23 is attached to the base member 17 with the rotation shaft 231 extending vertically downward.

At a tip part of the rotation shaft 231 protruding downward from the base member 17, attached is a first pulley 241. At a lower end part of the rotary shaft 22 of the substrate holder 2A, attached is a second pulley 242. In more detail, the lower end part of the rotary shaft 22 is inserted into the through hole provided in a spin chuck attachment portion 172 of the base member 17 and protrudes downward from the base member 17. This protruding portion is provided with the second pulley 242. Then, an endless belt 243 is put over between the first pulley 241 and the second pulley 242. Thus, in the present embodiment, the first pulley 241, the second pulley 242, and the endless belt 243 constitute the power transmitter 24.

Using the power transmitter 24 having the foregoing configuration makes it possible to select a long-length timing belt as the endless belt 243 and to encourage a longer life of the endless belt 243. As shown in FIG. 3, in the present embodiment, the motor 23 is arranged at a position facing the maintenance opening 11d1 of the chamber 11. Thus, detaching the lid member 19 from the chamber 11 to open the maintenance opening 11d1 exposes the power transmitter 24 and the motor 23 to the outside through the maintenance opening 11d1. This facilitates a maintenance operation by the operator to allow the maintenance operation to be performed with increased efficiency.

Moreover, the power transmitter 24 is arranged below the base member 17 while the other mechanisms described below are arranged above the base member 17. By adopting such an arrangement, it becomes possible for the operator to perform the maintenance operation more efficiently without considering interference with the other mechanisms.

The top surface of the spin chuck 21 is provided with suction holes 211, and a pump 26 is connected to the internal space of the suction holes 211 via piping 25 with an intervening valve (not shown). This pump 26 and the valve are electrically connected to the control unit 10 and operate in response to a command from the control unit 10. In this way, a negative pressure and a positive pressure are selectively applied to the spin chuck 21. If the pump 26 applies a negative pressure to the suction holes 211 of the spin chuck 21, for example, with the substrate S placed substantially in a horizontal posture on the top surface of the spin chuck 21, the spin chuck 21 sucks and holds the substrate S from below. On the other hand, if the pump 26 applies a positive pressure to the spin chuck 21, the substrate S can be taken out from the top surface of the spin chuck 21. Further, if the suction of the pump 26 is stopped, the substrate S is horizontally movable on the top surface of the spin chuck 21.

A nitrogen gas supplier 29 is connected to the spin chuck 21 via a pipe 28 provided in a central part of the rotary shaft 22. The nitrogen gas supplier 29 supplies a nitrogen gas at a normal temperature supplied from a utility of a factory, in which the substrate processing system 100 is installed, to the spin chuck 21 at a flow rate and a timing corresponding to a nitrogen gas supply command from the control unit 10, and causes the nitrogen gas to flow from the central part to a radially outer side on the side of a lower surface Sb of the substrate S. Note that although the nitrogen gas is used in the present embodiment, another inert gas may be used.

The rotating mechanism 2B includes a power transmitter 27 for not only rotating the spin chuck 21 integrally with the substrate S, but also rotating the rotating cup 31 in synchronization with the former rotation. The power transmitter 27 includes an annular member 27a made of a non-magnetic material or resin, spin chuck side magnets 27b built-in the annular member 27a, and cup side magnets 27v built-in a lower cup 32, which is one component of the rotating cup 31. The annular member 27a is attached to the rotary shaft 22 and rotatable about the axis of rotation AX together with the rotary shaft 22.

A plurality of spin chuck side magnets 27b are arranged radially and at equal angular intervals with the axis of rotation AX as a center on an outer peripheral edge part of the annular member 27a. In the present embodiment, an N-pole and an S-pole are respectively arranged on an outer side and an inner side of one of the two spin chuck side magnets 27b adjacent to each other, and an S-pole and an N-pole are respectively arranged on an outer side and an inner side of the other magnet.

Similarly to these spin chuck side magnets, a plurality of cup side magnets are arranged radially and at equal angular intervals with the axis of rotation AX as a center. These cup side magnets are built in the lower cup 32. The lower cup 32 is a constituent component of the scattering preventing mechanism 3 to be described next and, as shown in

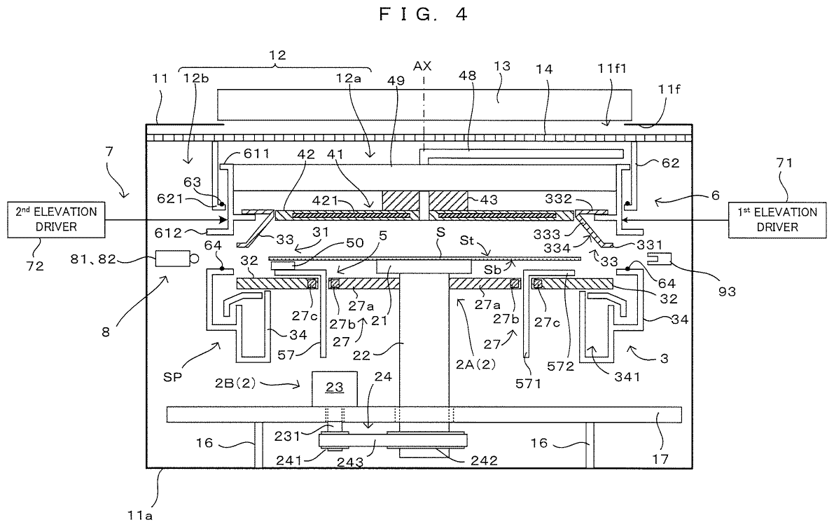

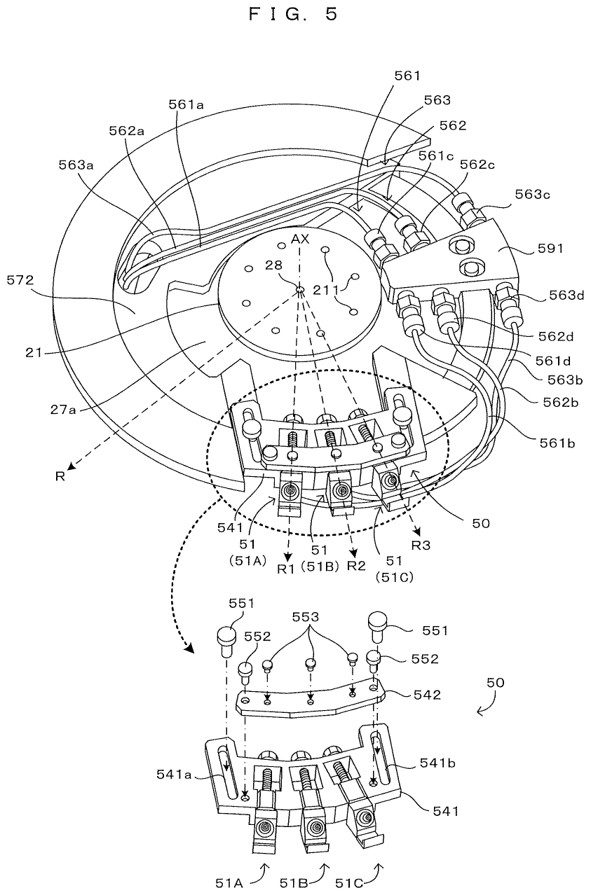

FIGS. 4 and 5, has an annular shape. That is, the lower cup 32 has an inner peripheral surface capable of facing the outer peripheral surface of the annular member 27a. An inner diameter of this inner peripheral surface is larger than an outer diameter of the annular member 27a. The lower cup 32 is arranged concentrically with the rotary shaft 22 and the annular member 27a while this inner peripheral surface is separated from the outer peripheral surface of the annular member 27a by a predetermined distance and facing the outer peripheral surface of the annular member 27a. Engaging pins 35 and coupling magnets (not shown) are provided on the top surface of the outer peripheral edge of the lower cup 32, the upper cup 33 is coupled to the lower cup 32 by these, and this coupled body functions as the rotating cup 31.

The lower cup 32 is supported rotatably about the axis of rotation AX on the top surface of the base member 17 while being kept in the above arranged state by a bearing not shown in figures. The plurality of cup side magnets are arranged radially and at equal angular intervals with the axis of rotation AX as a center on an inner peripheral edge part of this lower cup 32. Further, two cup side magnets adjacent to each other are arranged similarly to the spin chuck side magnets. That is, an N-pole and an S-pole are respectively arranged on an outer side and an inner side of one magnet, and an S-pole and an N-pole are respectively arranged on an outer side and an inner side of the other magnet.

At the power transmitter 27 thus configured, if the annular member 27a is rotated together with the rotary shaft 22 by the motor 23, the lower cup 32 rotates in the same direction as the annular member 27a while maintaining an air gap (gap between the annular member 27a and the lower cup 32) by the action of magnetic force between the spin chuck side magnet 27b and the cup side magnet 27c. In this way, at the power transmitter 27, the spin chuck side magnet 27b and the cup side magnet 27c form so-called magnet coupling to transmit rotational driving force on the spin chuck 21 to the rotating cup 31 via the magnet coupling. As a result, the rotating cup 31 rotates about the axis of rotation AX. When the substrate S rotates in response to the rotation of the spin chuck 21, the rotating cup 31 rotates in the same direction as and in synchronization with the substrate S.

The scattering preventing mechanism 3 includes the rotating cup 31 rotatable about the axis of rotation AX while surrounding the outer periphery of the substrate S held on the spin chuck 21 and a fixed cup 34 fixedly provided to surround the rotating cup 31. The rotating cup 31 is provided rotatably about the axis of rotation AX while surrounding the outer periphery of the rotating substrate S by the upper cup 33 being coupled to the lower cup 32.

The lower cup 32 has an annular shape. As shown in FIG. 2, the lower cup 32 has an outer diameter larger than that of the substrate S and is arranged rotatably about the axis of rotation AX while radially protruding from the substrate S held on the spin chuck 21 in a plan view vertically from above. In this protruding region, i.e. a top surface peripheral edge part 321 of the lower cup 32, the engaging pins (not shown) standing vertically upward and the flat plate-like lower magnets (not shown) are alternately mounted along a circumferential direction.

On the other hand, as shown in Fig, 2, the upper cup 33 includes a lower annular part 331, an upper annular part 332 and an inclined part 333 coupling these. An outer diameter of the lower annular part 331 is equal to an outer diameter of the lower cup 32 and the lower annular part 331 is located vertically above the peripheral edge part 321 of the lower cup 32. The inner peripheral surface of the upper annular part 332 and that of the lower annular part 331 are coupled by the inclined part 333 over the entire circumference of the upper cup 33. Thus, the inner peripheral surface of the inclined part 333, i.e. a surface surrounding the substrate S, serves as an inclined surface 334. That is, the inclined part 333 can collect liquid droplets scattered from the substrate S by surrounding the outer periphery of the rotating substrate S, and a space surrounded by the upper and lower cups 33, 32 functions as a collection space.

The inclined part 333 is inclined upwardly of the peripheral edge part of the substrate S from the lower annular part 331. Thus, liquid droplets collected by the inclined part 333 flow to a lower end part of the upper cup 33, i.e., to the lower annular part 331 along the inclined surface 334, and are then ejected to the outside of the rotating cup 31 via a gap from the lower cup 32.

The fixed cup 34 is provided in such a manner as to surround the rotating cup 31. The fixed cup 34 includes a liquid receiving part 341 and an exhaust part 342 provided inside the liquid receiving part 341. The liquid receiving part 341 has a cup structure open in such a manner as to surround the gap between the upper cup 33 and the lower cup 32 from outside. Specifically, an internal space of the liquid receiving part 341 functions as an ejection space. Thus, liquid droplets collected by the rotating cup 31 are guided together with a gas component to the liquid receiving part 341. Then, the liquid droplets are gathered in a bottom part of the liquid receiving part 341 and ejected from the fixed cup

On the other hand, the gas components are collected into the exhaust part 342. This exhaust part 342 is partitioned from the liquid receiving part 341 via a partition wall 343. Further, a gas guiding part 344 is arranged above the partition wall 343. The gas guiding part 344 extends horizontally from a position right above the partition wall 343, covering the partition wall 343 from above and forming a flow path for gas components with a labyrinth structure. Accordingly, the gas components, out of a fluid flowing into the liquid receiving part 341, are collected in the exhaust part 342 by way of the flow passage. This exhaust part 342 is connected to an exhaust part 38. Thus, a pressure in the fixed cup 34 is adjusted by the operation of the exhaust part 38 in response to a command from the control unit 10, and the gas components in the exhaust part 342 are efficiently exhausted.

The top surface protecting/heating mechanism 4 includes a shielding plate 41 arranged above the top surface St of the substrate S held on the spin chuck 21. This shielding plate 41 includes a disk part 42 held in a horizontal posture. The disk part 42 has a built-in heater 421 drive-controlled by a heater driver 422. This disk part 42 has a diameter slightly shorter than that of the substrate S. The disk part 42 is so supported by a support member 43 that the lower surface of the disk part 42 covers a surface region excluding the peripheral edge part Ss, out of the top surface St of the substrate S, from above.

A lower end part of the support member 43 is mounted in a central part of the disk part 42. The cylindrical through hole is formed to vertically penetrate through the support member 43 and the disk part 42. Further, a center nozzle 45 is vertically inserted into this through hole. As shown in FIG. 2, the nitrogen gas supplier 47 is connected to this center nozzle 45 via a pipe 46. The nitrogen gas supplier 47 heats a nitrogen gas at a normal temperature supplied from utilities of the factory in which the substrate processing system 100 is installed and supplies the heated gas to the center nozzle 45 at a flow rate and a timing corresponding to a heated gas supply command from the control unit 10.

Herein, when the heater 421 is disposed in the internal space 12 of the chamber 11, there is a possibility that the heat radiated from the heater 421 may adversely affect the substrate processing part SP, in particular, the processing mechanism 5 and the substrate observing mechanism 9 described later. Then, in the present embodiment, the nitrogen gas supplier 47 having the heater 421 is disposed outside the chamber 11 as shown in FIG. 3. Further, in the present embodiment, a ribbon heater 48 is mounted in a part of the pipe 46. The ribbon heater 48 generates heat in response to a heating command from the control unit 10 to heat the nitrogen gas flowing in the pipe 46.

The nitrogen gas (hereinafter, referred to as a “heated gas”) heated in this way is fed under pressure toward the center nozzle 45 and discharged from the center nozzle 45. For example, by supplying the heated gas with the disk part 42 positioned at a processing position near the substrate S held on the spin chuck 21, the heated gas flows toward a peripheral edge part from a central part of a space sandwiched between the top surface St of the substrate S and the disk part 42 including the built-in heater. In this way, an atmosphere around the substrate S can be suppressed from reaching the top surface St of the substrate S. As a result, the liquid droplets included in the atmosphere can be effectively prevented from getting in the space sandwiched between the substrate S and the disk part 42. Further, the top surface St is entirely heated by heating of the heater 421 and the heated gas, whereby an in-plane temperature of the substrate S can be made uniform. In this way, the warping of the substrate S can be suppressed and a liquid landing position of the processing liquid can be stabilized.

As shown in FIG. 2, an upper end part of the support member 43 is fixed to a beam member 49 extending the horizontal direction. This beam member 49 is connected to the elevating mechanism 7 installed on the top surface of the base member 17 and moved up and down by the elevating mechanism 7 in response to a command from the control unit 10. For example, in FIG. 2, the beam member 49 is positioned below, whereby the disk part 42 coupled to the beam member 49 is located at the processing position via the support member 43. On the other hand, if the elevating mechanism 7 moves up the beam member 49 in response to a move-up command from the control unit 10, the beam member 49, the support member 43 and the disk part 42 integrally move upward and the upper cup 33 is also linked, separated from the lower cup 32 and moves up. In this way, the upper cup 33 and the disk part 42 are spaced wider apart from the spin chuck 21 and the substrate S can be carried to and from the spin chuck 21.

The atmosphere separating mechanism 6 includes a lower sealing cup member 61 and an upper sealing cup member 62. Each of the upper and lower sealing cup members 61 and 62 has a cylindrical shape open vertically. The respective inner diameters of the upper and lower sealing cup members 61 and 62 are larger than the outer diameter of the rotating cup 31. The atmosphere separating mechanism 6 is arranged in such a manner as to completely surround the spin chuck 21, the substrate S held on the spin chuck 21, the rotating cup 31, and the top surface protecting/heating mechanism 4 from above. More particularly, as shown in FIG. 2, the upper sealing cup member 62 is fixedly arranged at a position right below the punching plate 14 in such a manner that the upper opening thereof covers the opening 11f1 of the ceiling surface 11f from below. Thus, a downflow of clean air introduced into the chamber 11 is separated into a flow passing through the inside of the upper sealing cup member 62 and a flow passing outside the upper sealing cup member 62.

The upper sealing cup member 62 has a lower end part provided with a flange part 621 having an annular shape folded internally. An O-ring 63 is mounted on a top surface of the flange part 611. The lower sealing cup member 61 is arranged movably in the vertical direction inside the upper sealing cup member 62.

The lower sealing cup member 61 has an upper end part provided with a flange part 611 having an annular shape bent to expand externally. The flange part 611 overlaps the flange part 621 in a plan view vertically from above. Thus, if the lower sealing cup member 61 moves down, the flange part 611 of the lower sealing cup member 61 is locked by the flange part 621 of the upper sealing cup member 62 via the O-ring 63. In this way, the lower sealing cup member 61 is located at a lower limit position. At this lower limit position, the upper sealing cup member 62 and the lower sealing cup member 61 are connected to each other in the vertical direction and a downflow introduced into the upper sealing cup member 62 is guided toward the substrate S held on the spin chuck 21.

The lower sealing cup member 61 has a lower end part provided with a flange part 612 having an annular shape with a diameter increased toward the outside. The flange part 612 overlaps an upper end part of the fixed cup 34 (upper end part of the liquid receiving part 341) in a plan view vertically from above. Thus, at the above-described lower limit position, the flange part 612 of the lower sealing cup member 61 is locked by the fixed cup 34 via an O-ring 64. In this way, the lower sealing cup member 61 and the fixed cup 34 are connected to each other in the vertical direction. As a result, a sealed space 12a is formed by the upper sealing cup member 62, the lower sealing cup member 61, and the fixed cup 34. The bevel process is implementable on the substrate S in the sealed space 12a.

Specifically, locating the lower sealing cup member 61 at the lower limit position separates the sealed space 12a from an outside space 12b outside the sealed space 12a (atmosphere separation). Thus, the bevel process can be performed stably without being influenced by an outside atmosphere. Furthermore, while a processing liquid is used for the bevel process, it is possible to reliably prevent the processing liquid from leaking from the sealed space 12a to the outside space 12b. This increases a degree of freedom in selecting/designing components to be arranged in the outside space 12b.

The lower sealing cup member 61 is also configured to be movable vertically upward. As shown in FIGS. 2 and 3, the top surface protecting/heating mechanism 4 is fixed to an intermediate part of the lower sealing cup member 61 via the beam member 49. Specifically, as shown in FIG. 4, the lower sealing cup member 61 is connected at its two positions different from each other in a peripheral direction to one end part and the other end part of the beam member 49 respectively. By causing the elevating mechanism 7 to move the one end part and the other end part of the beam member 49 up and down, the lower sealing cup member 61 is also moved up and down accordingly.

As shown in FIGS. 2 and 3, the lower sealing cup member 61 has an inner peripheral surface provided with a plurality of (four) projections 613 projecting internally and functioning as engagement parts engageable with the upper cup 33. Each of the projections 613 extends to a space below the upper annular part 332 of the upper cup 33. Each of the projections 613 is mounted in such a manner as to be separated downward from the upper annular part 332 of the upper cup 33 with the lower sealing cup member 61 located at the lower limit position. In response to upward movement of the lower sealing cup member 61, each of the projections 613 becomes engageable with the upper annular part 332 from below. By moving up the lower sealing cup member 61 further after the engagement, the upper cup 33 becomes separable from the lower cup 32.

FIG. 4 shows a state where the upper cup is a moved-up position. More specifically, FIG. 4 shows a state where the lower sealing cup member 61 has moved up the upper cup 33 in response to the actuation of the elevating mechanism 7. In this regard, FIG. 4 is a counterpart of FIG. 2 showing a state where the upper cup 33 is in a moved-down positions. The structures shown in FIGS. 2 and 4 are basically the same with only a difference in terms of a positional relationship between some of the structures. Thus, some of the structures shown in FIG. 2 not relating directly to the description given herein are omitted from FIG. 4.

In the present embodiment, after the lower sealing cup member 61 starts to be moved up together with the top surface protecting/heating mechanism 4 by the elevating mechanism 7, the projections 613 of the lower sealing cup member 61 engage with the upper cup 33 to move up the upper cup 33 together, as shown in FIG. 4. By doing so, the upper cup 33 and the top surface protecting/heating mechanism 4 are separated upward from the spin chuck 21. In response to movement of the lower sealing cup member 61 to a retracted position, a conveyance space for allowing the hand of the substrate conveyor robot 111 to access the spin chuck 21 is formed. Then, loading of the substrate S onto the spin chuck 21 and unloading of the substrate S from the spin chuck 21 become possible via the conveyance space. In this way, in the present embodiment, it is possible for the substrate S to access the spin chuck 21 in response to minimum upward movement of the lower sealing cup member 61 caused by the elevating mechanism 7.

The elevating mechanism 7 includes two elevation drivers, specifically, a first elevation driver 71 and a second elevation driver 72. At the elevation driver 71, a first elevation motor (not shown) is mounted on the base member 17. The first elevation motor operates in response to a drive command from the control unit 10 to generate rotational force. An elevator 712 is coupled to the first elevation motor. The elevator 712 is coupled to the one end part of the beam member 49 via a side surface of the lower sealing cup member 61. If the elevator 712 receives the above-described rotational force from the first elevation motor, the elevator 712 moves the one end part of the beam member 49 up and down in the vertical direction Z in response to the amount of rotation of the first elevation motor.

In the elevation driver 72, a second elevation motor (not shown) is mounted on the base member 17. An elevator 722 is coupled to the second elevation motor. The second elevation motor operates in response to a drive command from the control unit 10 to generate rotational force, and applies the generated rotational force to the elevator 722. The elevator 722 is coupled to the other end part of the beam member 49 via the side surface of the lower sealing cup member 61, and moves the other end part of the beam member 49 up and down in the vertical direction in response to the amount of rotation of the second elevation motor.

The elevation drivers 71 and 72 move the side surface of the lower sealing cup member 61 in the vertical direction while forming synchronization between two positions on this side surface different from each other in a peripheral direction. By doing so, it becomes possible to move the top surface protecting/heating mechanism 4 and the lower sealing cup member 61 to up and down stably. It further becomes possible to move the upper cup 33 up and down stably in response to the upward and downward movements of the lower sealing cup member 61.

The centering mechanism 8 is basically a publicly-known mechanism, so that it will be described briefly next. The centering mechanism 8 performs a centering process while suction by the pump 26 is stopped (i.e. while the substrate S is horizontally movable on the top surface of the spin chuck 21). As a result of implementation of the centering process, the eccentricity of the substrate S is eliminated to align the center of the substrate S with the axis of rotation AX. As shown in FIG. 3, the centering mechanism 8 includes a single contact part 81 and a multi-contact part 82 arranged on opposite sides to each other across the axis of rotation AX of the spin chuck 21, and a centering driver 83 for moving the single contact part 81 and the multi-contact part 82 in a contact movement direction.

The centering driver 83 moves in a direction of approaching the substrate S on the spin chuck 21 while bringing the single contact part 81 and the multi-contact part 82 into conjunction with each other, thereby adjusting the position of the substrate S in such a manner as to bring both one contact position of the single contact part 81 and two contact positions of the multi-contact part 82 into contact with an end surface of the substrate S. By doing so, the eccentricity of the substrate S on the spin chuck 21 is eliminated to realize the centering.

The processing mechanism 5 will be described next. As shown in FIG. 3, the processing mechanism 5 includes a nozzle block 50 arranged adjacent to the lower surface

Sb of the substrate S, and a processing liquid supplier 59 that supplies a processing liquid to the nozzle block 50. The nozzle block 50 includes three processing liquid discharge nozzles 51A, 51B, and 51C (FIG. 5) each used for discharging the processing liquid, and a support mechanism 54 that supports the processing liquid discharge nozzles 51A, 51B, and 51C. As will be described later, the support mechanism 54 is configured to make the position of each of the processing liquid discharge nozzles 51A, 51B, and 51C adjustable relative to the substrate S in the peripheral direction of the substrate S.

The processing liquid supplier 59 is connected to the three processing liquid discharge nozzles 51A, 51B, and 51C. The processing liquid supplier 59 is configured to allow supply of processing liquids that may be chemical liquids such as an SC1 liquid and DHF (diluted hydrofluoric acid), and functional water (CO2 water, for example). The SC1 liquid, the DHF, and the functional water are dischargeable independently of each other from the three discharge nozzles 51A, 51B, and 51C.

As shown in FIG. 2, in the present embodiment, a nozzle support 57 supporting the nozzle block 50 is provided below the substrate S held on the spin chuck 21 in order to discharge the processing liquid toward a peripheral edge part of the lower surface Sb of the substrate S. The nozzle support 57 includes a thin circular cylindrical part 571 extending in the vertical direction, and a flange part 572 having an annular shape provided at an upper end part of the circular cylindrical part 571 and bent to expand radially externally. The circular cylindrical part 571 has a shape allowing the circular cylindrical part 571 to be loosely inserted into the air gap formed between the annular member 27a and the lower cup 32. As shown in FIG. 2, the nozzle support 57 is fixedly arranged in such a manner that the circular cylindrical part 571 is loosely inserted in the air gap and the flange part 572 is located between the substrate S held on the spin chuck 21 and the lower cup 32. The nozzle block 50 is mounted on a part of a peripheral edge part of a top surface of the flange part 572.

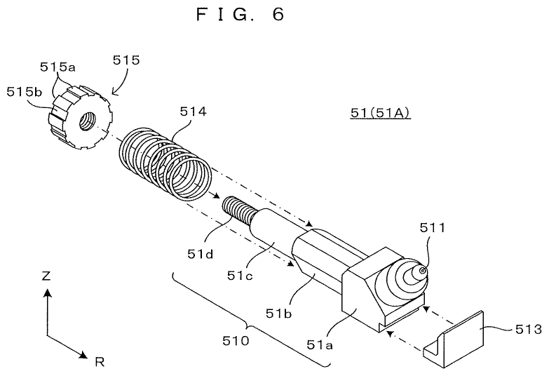

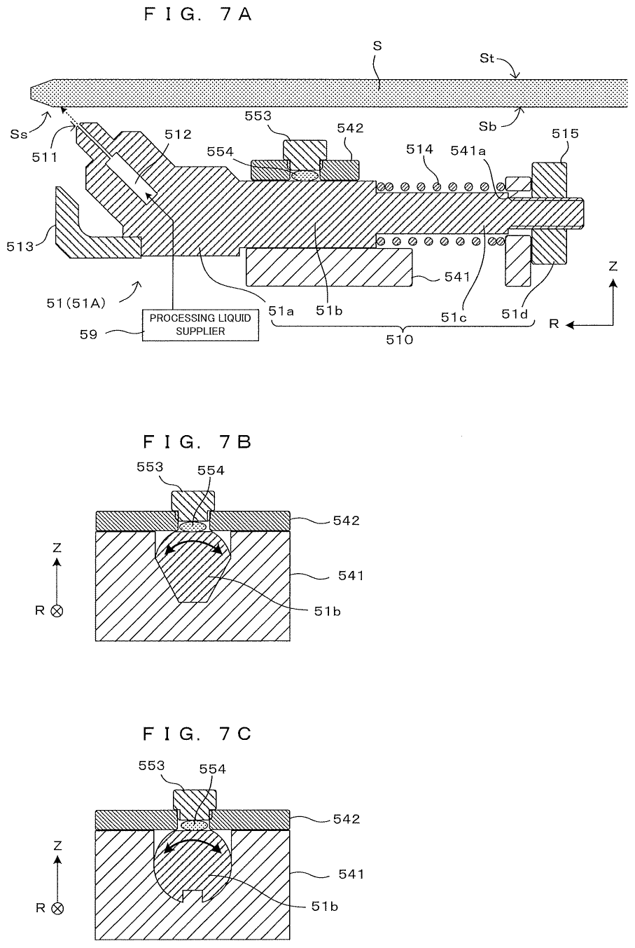

FIG. 5 shows the configuration and layout of the processing mechanism. FIG. 6 is an exploded perspective view showing the configuration of one processing liquid discharge nozzle. FIG. 7 shows a sectional configuration of this processing liquid discharge nozzle. In the following, a direction extending horizontally and outwardly from the axis of rotation AX of the spin chuck 21 may be called a moving radius direction R. The moving radius direction R corresponds to a radial direction of the substrate S held on the spin chuck 21, particularly, an outward direction from the center of the substrate S.

As shown in FIG. 5, the nozzle block 50 is mounted on the flange part 572 having a substantially annular shape provided at the top of the nozzle support 57. The support mechanism 54 of the nozzle block 50 includes a base member 541 and a pressure member 542. The base member 541 supports the three processing liquid discharge nozzles 51A, 51B, and 51C collectively.

The base member 541 has opposite ends where long holes 541a and 541b are formed. Fastening members 551, 551 such as screws passed through these holes are threadedly engaged with screw holes formed at the flange part 572, thereby fixing the base member 541 to the flange part 572. This allows a position of mounting of the base member 541 on the flange part 572 to be changed within a predetermined range. As a result, it is possible to adjust the positions of the three processing liquid discharge nozzles 51A, 51B, and 51C integrally.

The three processing liquid discharge nozzles 51A, 51B, and 51C have the same shape. Here, the processing liquid discharge nozzle 51A will be given as an example and the configuration thereof will be described by referring to FIGS. 6 and 7. In the following description, where the processing liquid discharge nozzles 51A, 51B, and 51C are not required to be distinguished from each other, these nozzles may simply be called a “processing liquid discharge nozzle 51.” FIG. 7A is a longitudinal sectional view of the processing liquid discharge nozzle 51. As shown in FIGS. 7A and 6, a nozzle body 510 forming a principal part of the processing liquid discharge nozzle 51 has a long and narrow shape extending in the moving radius direction R, and includes a nozzle head part 51a, a large-diameter shaft part 51b, a small-diameter shaft part 51c, and a male screw part 51d arranged in this order in a (−R) direction.

The nozzle head part 51a of the processing liquid discharge nozzle 51 arranged on the (+R) side has a tip where a discharge port 511 for discharge of the processing liquid is provided. After the processing liquid is supplied via an internal manifold 512 from the processing liquid supplier 59, the processing liquid is discharged from the discharge port 511 diagonally upward at an elevation angle of 45 degrees and outward as viewed from the axis of rotation AX. The processing liquid is discharged toward a lower surface peripheral edge part Ss of the substrate S.

If a metallic thin film or a thin film of a metallic compound is formed on the lower surface Sb of the substrate S and the discharged processing liquid has solubility in this coating film, the thin film on the substrate lower surface Sb is removed by etching in a region where the processing liquid has landed. If the substrate S rotates, the processing liquid is spread externally from the liquid landing position by the action of centrifugal force. As a result, the thin film external to the liquid landing position is removed.

The nozzle head part 51a has a bottom mounted with a reflection member 513 having a (+R) side end surface functioning as a planar reflection surface. The reflection member 513 is used in measuring a nozzle position using a laser displacement meter, for example, and achieves accurate and stable position measurement by reflecting laser light emitted from the laser displacement meter.

The large-diameter shaft part 51b engages with a groove formed at the base member 541. As shown in FIGS. 7B and 7C, the large-diameter shaft part 51b has a cross-sectional plane of a non-circular constant shape. The groove conforming to this sectional shape is formed at the base member 541. Thus, while the processing liquid discharge nozzle 51 is movable in the moving radius direction R within a certain range relative to the base member 541, rotation of the processing liquid discharge nozzle 51 in a direction indicated by arrowed thick lines in FIGS. 7B and 7B is restricted. This prevents fluctuation in a direction of discharging the processing liquid.

The sectional shape of the large-diameter shaft part 51b is not limited to those described above but can be various non-circular shapes. This sectional shape is preferably a shape to avoid the occurrence of rattling motion as well as a shape simply avoiding rotation within the groove of the base member. The shape shown in each of FIGS. 7B and 7C is an exemplary shape preferable in terms of fulfilling the function of regulating displacement of the large-diameter shaft part 51b in a lateral direction of the plane of the sheet when the pressure member 542 is mounted.

The large-diameter shaft part 51b has a top pressed with the pressure member 542, and the pressure member 542 is fixed to the base member 541 with a fastening member 552 such as a screw. This makes it unlikely that the large-diameter shaft part 51b will be displaced upward to come off the base member 541. The pressure member 542 is further mounted with a fixing screw 553. If the fixing screw 553 is tightened after position adjustment, the fixing screw 553 presses the large-diameter shaft part 51b via an appropriate cushion member 554. By doing so, displacement of the processing liquid discharge nozzle 51 in the R direction is restricted.

The small-diameter shaft part 51c is provided continuously with the large-diameter shaft part 51b on the (−R) side relative to the large-diameter shaft part 51b. The male screw part 51d is provided continuously with the small-diameter shaft part 51c on the (−R) side relative to the small-diameter shaft part 51c. The small-diameter shaft part 51c is provided with a coil spring 514. The male screw part 51d extends further toward the (−R) side via a through hole formed at a (−R) side end of the base member 541. An adjusting nut 515 is threadedly engaged with the male screw part 51d.

Thus, the state of the processing liquid discharge nozzle 51 is such that, while the processing liquid discharge nozzle 51 is biased in the (+R) direction by the coil spring 514, displacement resulting from the biasing force is regulated by the adjusting nut 515. For this reason, if an operator rotates the adjusting nut 515 in either direction, the position of the discharge port 511 is displaced either in the (+R) direction or in the (−R) direction in response to the rotation. By doing so, it becomes possible to adjust the position of the discharge port 511 in the radial direction of the substrate S.

The adjusting nut 515 restricts displacement against the biasing force from the coil spring 514 to define a nozzle position. This configuration makes it possible to realize nozzle position adjustment insusceptible to influence by backlash or rattling motion.

The processing liquid discharge nozzle 51 (51A to 51C) and the support mechanism 54 are composed of a material having excellent chemical resistance such as a resin material, for example. As an example, a material to be used is suitably selectable from a polyethylene resin, a polytetrafluoroethylene (PTFE) resin, and a polyetheretherketone (PEEK) resin in response to a purpose. Of these materials, the PEEK resin is preferably applicable to the coil spring 514 as a material thereof requires an appropriate degree of elasticity.

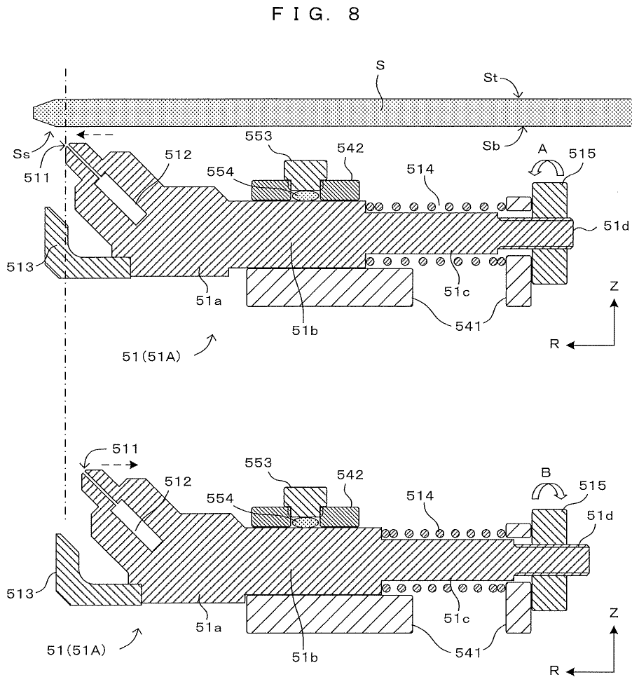

FIG. 8 explains the action of nozzle position adjustment fulfilled by the processing mechanism. As indicated by an arrow A in the upper view of FIG. 8, if the adjusting nut 515 is rotated relative to the male screw part 51d in a direction of loosening the adjusting nut 515 (in the case of a right-hand screw), the adjusting nut 515 moves in the (−R) direction, specifically, in the rightward direction of the drawing relative to the nozzle body 510. Actually, the processing liquid discharge nozzle 51 is entirely biased in the (+R) direction relative to the base member 541 by the biasing force from the coil spring 514. This displaces the nozzle body 510 in the (+R) direction while keeping the position of the adjusting nut 515 unchanged.

By doing so, as indicated by an arrowed dashed line, the discharge port 511 is displaced to the left of the drawing, namely, to the (+R) direction. As a result, a liquid landing position of the processing liquid on the substrate lower surface Sb discharged from the discharge port 511 is also moved in the (+R) direction, namely, toward an external side of the substrate S. Thus, an etching width is reduced.

Meanwhile, as indicated by an arrow B in the lower view of FIG. 8, if the adjusting nut 515 is rotated relative to the male screw part 51d in a direction of tightening the adjusting nut 515 (in the case of a right-hand screw), the adjusting nut 515 moves in the (+R) direction, specifically, in the leftward direction of the drawing relative to the nozzle body 510. In this case, the position of the adjusting nut 515 is also actually kept unchanged and the nozzle body 510 is displaced in the (−R) direction by the action of the coil spring 514.

By doing so, as indicated by an arrowed dashed line, the discharge port 511 is displaced to the right of the drawing, namely, to the (−R) direction. As a result, the liquid landing position of the processing liquid on the substrate lower surface Sb discharged from the discharge port 511 is also moved in the (−R) direction, namely, toward the center the substrate S. This increases an etching width. In this way, it is possible to increase or reduce an etching width by moving the nozzle position in the R direction.

As shown in FIG. 6, the adjusting nut 515 has an outer peripheral surface with periodic projections and recesses. More specifically, 10 projections 515a and 10 recesses 515b are formed alternately at a regular angular interval at the outer peripheral surface of the adjusting nut 515. These projections and recesses function as scales indicating the amount of displacement of the nozzle body 510 quantitatively during the nozzle position adjustment.

The amount of displacement of the nozzle body 510 in the R direction is determined according to a relationship between the rotation angle of the adjusting nut 515 and a screw pitch of the male screw part 51d. If the pitch of the male screw part 51d is 0.5 mm, for example, the nozzle body 510 is displaced in units of 0.5 mm in response to one rotation of the adjusting nut 515. In this regard, assuming that the projections and the recesses form pairs equally dividing the outer peripheral surface of the adjusting nut 515 into ten as described above and each of the pairs functions as one scale, the nozzle body 510 moves in units of 50 μm in response to each rotation of the adjusting nut 515 by one scale.

The respective lengths of the projection 515a and the recess 515b in the peripheral direction are not required to be equal to each other. By setting these lengths equally, however, the projections 515a and the recesses 515b can effectively be considered to be scales equally dividing one periphery into 20. In this case, a stroke corresponding to one scale is 25 μm. Providing the scales at the outer peripheral surface of the adjusting nut 515 in this way allows visualization of the stroke of the nozzle body 510, eventually, allows visualization of the amount of change in an etching width during the adjusting operation. By doing so, it becomes possible to reduce the number of repetitions of an operation of actually measuring an etching width after the adjusting operation and making an adjustment again, thereby allowing the adjusting operation to be performed more efficiently.

The description will be continued by referring back to FIG. 5. The processing liquid discharge nozzles 51A to 51C have the respective configurations described above. The base member 541 of the support mechanism 54 supports the nozzles 51A to 51C at a regular angular interval in such a manner that the respective longitudinal directions of the nozzles 51A to 51C conform to the moving radius direction R. This allows the nozzle block 50 to realize a coarse adjusting mode and a fine adjusting mode by adjusting the position of the base member 541 relative to the nozzle support 57 (flange part 572). In the coarse adjusting mode, the three processing liquid discharge nozzles 51A to 51C are moved integrally with a large stroke. In the fine adjusting mode, the three processing liquid discharge nozzles 51A to 51C are moved individually and finely relative to the base member 541. In the present embodiment, by employing these adjusting modes in combination, it becomes possible to adjust the position of each of the processing liquid discharge nozzles 51A to 51C with a large stroke and with fineness.

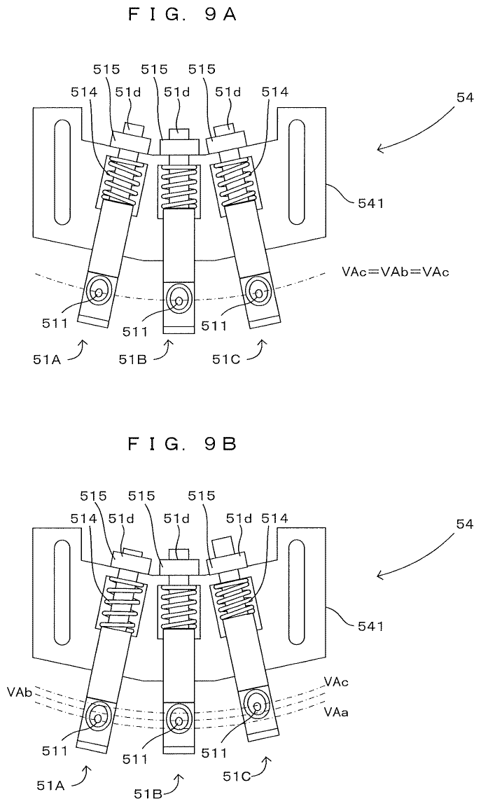

In the present embodiment, to allow implementation of the fine adjusting mode, the base member 541, the male screw part 51d, the coil spring 514, and the adjusting nut 515 each have a predetermined positional relationship with the discharge port 511 of each of the processing liquid discharge nozzles 51A to 51C. This will be described below by referring to FIGS. 9A and 9B.

FIGS. 9A and 9B show a positional relationship viewed from vertically above between the discharge port, the base member, the male screw part, the coil spring, and the adjusting nut. These drawings show a case where an adjustment is made in such a manner that the respective discharge ports 511 of the processing liquid discharge nozzles 51A to 51C are at the same position in the moving radius direction R (FIG. 9A), and a case where an adjustment is made in such a manner that the respective discharge ports 511 of the processing liquid discharge nozzles 51A to 51C are at different positions in the moving radius direction R (FIG. 9B).

In these drawings, each dash-dotted line indicates a virtual arc centered on the axis of rotation AX (FIG. 5) and passing through the discharge port 511. The “virtual arc” means an arc defined by cutting out a part including the discharge port 511 and its vicinity from a virtual circle centered on the axis of rotation AX and having a radius defined by a distance from the axis of rotation AX to the discharge port 511. In the case shown in FIG. 9A, virtual arcs VAa to VAc corresponding to the processing liquid discharge nozzles 51A to 51C respectively are aligned with each other. Furthermore, the base members 541, the male screw parts 51d, the coil springs 514, and the adjusting nuts 515 are arranged internal to the virtual arcs VAa to VAc (above these arcs in FIG. 9A) and are always present internal to the discharge ports 511 in the moving radius direction R in a plan view from vertically above. In the case shown in FIG. 9B, while the virtual arcs VAa to VAc corresponding to the processing liquid discharge nozzles 51A to 51C respectively are not aligned with each other, the arrangement is similar to the case of FIG. 9A. While not shown in FIGS. 9A and 9B, if virtual arcs corresponding to two of the processing liquid discharge nozzles 51 are aligned with each other, the base members 541, the male screw parts 51d, the coil springs 514, and the adjusting nuts 515 are also arranged internal to the virtual arcs VAa to VAc and are always present internal to the discharge ports 511 in the moving radius direction R in a plan view from vertically above.

As described above, the structures for adjusting the position of the discharge port 511 in the moving radius direction R are arranged internal to the discharge port 511 to prevent these structures from going beyond the discharge port 511 externally. Furthermore, in the present embodiment, the discharge port 511 is provided in such a manner that the processing liquid is discharged diagonally upward at an elevation angle of 45 degrees and outward as viewed from the axis of rotation AX. This makes it possible to control a planar size while realizing the fine adjusting mode, thereby allowing downsizing of the substrate processing apparatus 1. As a result, it is possible to reduce the usage of gas in the substrate processing apparatus 1 to allow reduction in environmental load.

The processing liquid supplied to the lower surface peripheral edge part Ss of the substrate S is scattered. In this case, if all or some of the structures for adjusting the position of the discharge port 511 are present external to the discharge port 511 in the moving radius direction R, these structures may disperse the processing liquid scattered from the lower surface peripheral edge part Ss and may move the processing liquid back to the substrate S. By contrast, in the substrate processing apparatus 1 having the foregoing configuration, all the base member 541, the male screw part 51d, the coil spring 514, and the adjusting nut 515 are always present internal to the discharge port 511, thereby preventing the foregoing problem reliably.

Furthermore, in the present embodiment, the rotating cup 31 rotates about the axis of rotation AX while surrounding the outer periphery of the rotating substrate S and collects droplets of the processing liquid scattered from the substrate S. This makes it difficult to arrange all or some of the structures for adjusting the position of the discharge port 511 external to the discharge port 511 in the moving radius direction R. In this regard, in the substrate processing apparatus 1 having the above-described configuration, it is possible to provide both the rotating cup 31 and fine adjustment of the discharge port 511 of each of the processing liquid discharge nozzles 51A to 51C.

The description will be continued by referring back to FIG. 5. A pipe 56 for supplying the processing liquids to the processing liquid discharge nozzles 51A to 51C has an arrangement as follows. Specifically, pipes 561, 562, and 563 for feeding the processing liquids from the processing liquid supplier 59 to the nozzles 51A, 51B, and 51C respectively are composed of flexible tubes. Each of the pipes 561, 562, and 563 is divided into an upstream pipe and a downstream pipe by a relay block 591 mounted on the flange part 572 of the nozzle support 57.

More specifically, the pipe 561 for supplying the SC1 liquid to the processing liquid discharge nozzle 51A is divided into an upstream pipe 561a upstream from the relay block 591 and a downstream pipe 561b downstream from the relay block 591. The upstream pipe 561a and the relay block 591 are connected to each other via a joint 561c. The downstream pipe 561b and the relay block 591 are connected to each other via a joint 561d. The upstream pipe 561a extends from below the chamber 11 to the top of the flange part 572 through the air gap between the annular member 27a and the lower cup 32. The SC1 liquid supplied from the processing liquid supplier 59 passes through inside the upstream pipe 561a. The SC1 liquid further passes through the downstream pipe 561b and is finally discharged from the processing liquid discharge nozzle 51A.

Likewise, the pipe 562 for supplying the DHF to the processing liquid discharge nozzle 51B is divided into an upstream pipe 562a upstream from the relay block 591 and a downstream pipe 562b downstream from the relay block 591. The upstream pipe 562a and the relay block 591 are connected to each other via a joint 562c. The downstream pipe 562b and the relay block 591 are connected to each other via a joint 562d. The upstream pipe 562a extends from below the chamber 11 to the top of the flange part 572 through the air gap between the annular member 27a and the lower cup 32. The DHF supplied from the processing liquid supplier 59 passes through inside the upstream pipe 562a. The DHF passes through the downstream pipe 562b and is finally discharged from the processing liquid discharge nozzle 51B.

The pipe 563 for supplying the functional water (CO2 water) to the processing liquid discharge nozzle 51C is divided into an upstream pipe 563a upstream from the relay block 591 and a downstream pipe 563b downstream from the relay block 591. The upstream pipe 563a and the relay block 591 are connected to each other via a joint 563c. The downstream pipe 563b and the relay block 591 are connected to each other via a joint 563d. The upstream pipe 563a extends from below the chamber 11 to the top of the flange part 572 through the air gap between the annular member 27a and the lower cup 32. The functional water supplied from the processing liquid supplier 59 passes through inside the upstream pipe 563a. The functional water passes through the downstream pipe 563b and is finally discharged from the processing liquid discharge nozzle 51C.

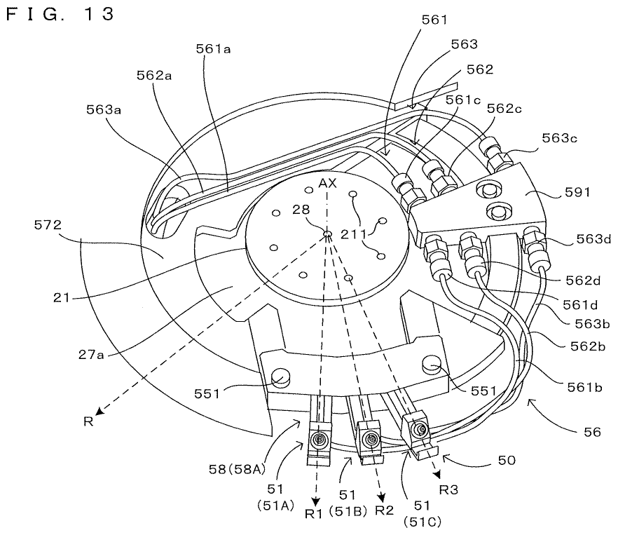

Dividing each of the pipes into the upstream side and the downstream side using the relay block 591 allows the pipes to be routed independently of each other. This allows the pipes to be housed even in a narrow space around the spin chuck 21. This further allows the pipes to be passed without causing influence on transmission of rotational force via the magnet coupling. This also applies to embodiments described later by referring to FIGS. 13, 20, and 21.

The substrate observing mechanism 9 will be described next. The substrate observing mechanism 9 is a mechanism for observing the peripheral edge part Ss of the processed substrate S optically for the purpose of judging whether the substrate S has been processed properly.

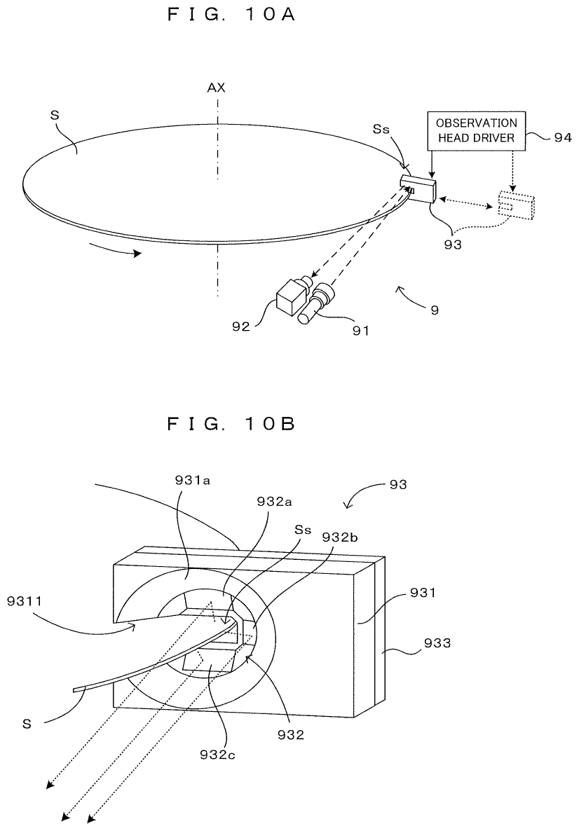

FIGS. 10A and 10B show the configuration of the substrate observing mechanism. More specifically, FIG. 10A schematically shows the motion of the substrate observing mechanism 9, and FIG. 10B is a perspective view showing an observation head 93 of the substrate observing mechanism 9. The substrate observing mechanism 9 includes a light source part 91, an image pickup part 92, the observation head 93, and an observation head driver 94. The light source part 91 and the image pickup part 92 are juxtaposed to each other at the base member 17. In response to a lighting command from the control unit 10, the light source part 91 emits illumination light toward an observation position. This observation position is a position corresponding to the peripheral edge part Ss of the substrate S, which corresponds to a position where the observation head 93 is indicated by solid lines in FIG. 10A.

The observation head 93 is reciprocally movable between the observation position and a retracted position (dotted lines) separated externally from the observation position in the radial direction of the substrate S. The observation head driver 94 is connected to the observation head 93. The observation head driver 94 is mounted on the base member 17. In response to a head moving command from the control unit 10, the observation head driver 94 causes the observation head 93 to move reciprocally. More specifically, when a process of observing the substrate S is not intended, the observation head driver 94 moves the observation head 93 to the retracted position and locates the observation head 93 at the retracted position. This separates the observation head 93 from a conveyance path of the substrate S, making it possible to effectively prevent the observation head 93 from interfering with the substrate S loaded into or unloaded from the chamber 11. Meanwhile, when the process of observing the substrate S is intended, the observation head driver 94 moves the observation head 93 to the observation position in response to a substrate observing command from the control unit 10.

As shown in FIG. 10B, the observation head 93 includes a diffused lighting part 931 having a diffusion surface 931a, a guide 932 consisting of three mirror members 932a to 932c, and a holder 933.

The diffused lighting part 931 is composed of PTFE, for example. The diffused lighting part 931 has a plate shape extending in the horizontal direction and is provided with a cut 9311 formed at an end part thereof adjacent to the substrate S. The cut 9311 has a size in the vertical direction greater than the thickness of the substrate S. When the observation head 93 is located at the observation position, the cut 9311 gets into the peripheral edge part Ss of the substrate S and further into a region internal to the peripheral edge part Ss in the radial direction. The cut 9311 has an inverted C shape as viewed from the peripheral direction of the substrate S. The diffused lighting part 931 is provided with an inclined surface extending along the cut 9311. The inclined surface is a tapered surface that is finished in such a manner as to be inclined further toward a direction in which the illumination light travels with a shorter distance to the cut 9311.

The holder 933 is composed of PEEK, for example, and is provided with a cut at an end part thereof adjacent to the substrate S similar to the cut formed at the diffused lighting part 931. The holder 933 is finished into a shape mutually engageable with the diffused lighting part 931.

Locating the observation head 93 having the above-described configuration at the observation position locates the diffusion surface 931a in a lighting area to be lighted with the light source part 91. If the light source part 91 is lighted in this positioning state in response to a lighting command from the control unit 10, illumination light is emitted to the lighting area. At this time, the diffusion surface 931a diffusedly reflects the illumination light to illuminate the peripheral edge part Ss of the substrate S and an adjacent area thereof from various directions. As indicated by arrowed dotted lines in FIG. 10B, at the peripheral edge part Ss of the substrate S and in the vicinity thereof, light reflected on the top surface is partially reflected by the mirror member 932a. Light reflected on an end surface of the substrate S is partially reflected by the mirror member 932b. Light reflected on the lower surface of the substrate S is partially reflected by the mirror member 932c. These reflected rays of light are guided into the image pickup part 92.

The image pickup part 92 includes an observation lens system consisting of an object-side telecentric lens, and a CMOS camera. Thus, only a ray of the reflected light guided from the observation head 93 and parallel to an optical axis of the observation lens system enters a sensor surface of the CMOS camera to form an image including the peripheral edge part Ss of the substrate S and the adjacent area thereof on the sensor surface. In this way, the image pickup part 92 images the peripheral edge part Ss of the substrate S and the adjacent area thereof to acquire a top surface image, a side surface image, and a lower surface image of the substrate S. Then, the image pickup part 92 transmits image data representing the acquired images to the control unit 10.

While the observation head 93 is arranged at a position near the peripheral edge part of the substrate S as needed, the light source part 91 and the image pickup part 92 are arranged at positions sufficiently farther from the substrate S than the observation head 93. This results in extremely low probability that, even if a liquid adheres to the substrate S, the liquid will adhere to the light source part 91 and the image pickup part 92 to become a hindrance to imaging.

The control unit 10 includes an arithmetic processor 10A, a storage 10B, a reader 10C, an image processor 10D, a drive controller 10E, a communicator 10F, and an exhaust controller 10G. The storage 10B is constituted by a hard disk drive or the like, and stores a program for causing the substrate processing apparatus 1 to perform the bevel process.

This program is stored, for example, in a computer-readable recording medium RM (e.g. an optical disk, a magnetic disk, a magneto-optical disk, or the like), read from the recording medium RM by the reader 10C, and saved in the storage 10B. The program is not always required to be provided from the recording medium RM but may be configured to be provided via an electrical communication line, for example. The image processor 10D performs various types of processing on an image obtained by imaging by the substrate observing mechanism 9. The drive controller 10E controls each driver of the substrate processing apparatus 1. The communicator 10F communicates with a controller that integrally controls components of the substrate processing system 100, and with others.

The exhaust controller 10G controls the exhaust part 38.

A display unit 10H (a display, for example) for displaying various types of information and an input unit 10J (a keyboard and a mouse, for example) for receiving an input from an operator are connected to the control unit 10.

The arithmetic processor 10A is constituted by a computer including a CPU (central processing unit), a RAM (random access memory) and others, and performs a predetermined operation by controlling each part of the substrate processing apparatus 1 by following the program stored in the storage 10B. The arithmetic processor 10A achieves implementation of the bevel process described above, for example.

Described next is the operation of adjusting a nozzle position in the processing unit 1 having the above-described configuration. A nozzle position is required to be adjusted prior to implementation of the bevel process of removing a thin film from the peripheral edge part Ss of the substrate S in order to achieve a target etching width. The reason for this is that, as described above, an etching width is determined by a liquid landing position of the processing liquid from the nozzle and the liquid landing position is influenced by the nozzle position.

The operation of adjusting the nozzle position may be performed as follows, for example. First, with the processing liquid discharge nozzles 51A to 51C provisionally mounted on the support mechanism 54 of the nozzle block 50, the nozzle block 50 is mounted on the flange part 572 with the fastening member 551. At this time, a position of mounting of the support mechanism 54 on the flange part 572 is adjusted in the coarse adjusting mode responsive to a required etching width. This makes it possible to adjust the positions of a plurality of nozzles integrally with a large stroke while accuracy of the adjustment is not always high. For example, an adjustment range of about 20 mm can be ensured.

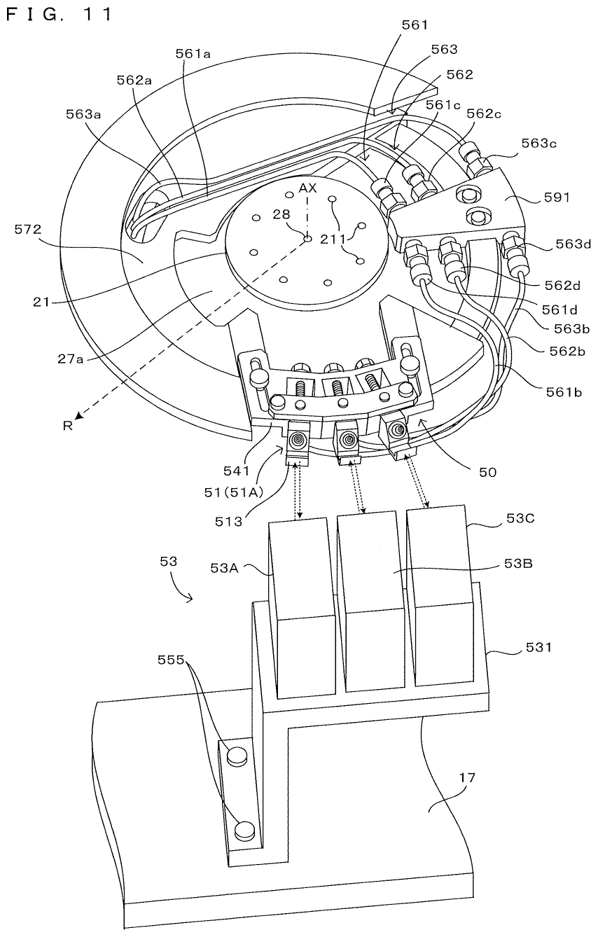

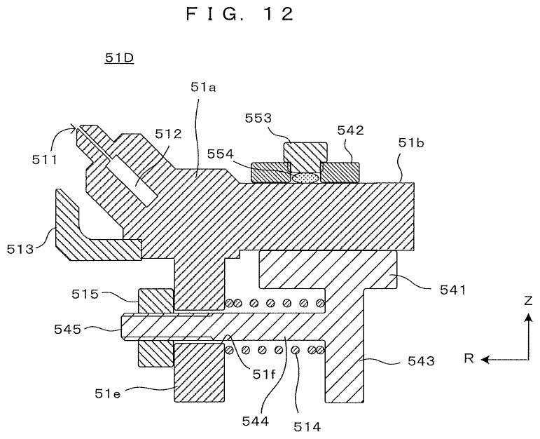

Next, the position of each of the processing liquid discharge nozzles 51A to 51C is adjusted in the fine adjusting mode. The position of each of the processing liquid discharge nozzles 51A to 51C may be adjusted finely as follows, for example. FIG. 11 schematically shows the nozzle position adjustment in the fine adjusting mode. In the fine adjusting mode, a laser measuring unit 53 is introduced. The laser measuring unit 53 includes three laser displacement meters 53A, 53B, and 53C corresponding to the three processing liquid discharge nozzles 51A, 51B, and 51C respectively, and a support frame 531 supporting the displacement meters. The support frame 531 is mountable on the base member 17 supporting the substrate processing part SP, for example.

Specifically, a female screw for fixing the support frame 531 is formed in advance at the base member 17, and the support frame 531 is fixed to the base member 17 using a fastening member 555 as needed. By doing so, it becomes possible to locate the laser displacement meters 53A, 53B, and 53C at respective appropriate positions corresponding to the three processing liquid discharge nozzles 51A, 51B, and 51C respectively.

The laser displacement meter 53A emits laser light for distance measurement to the corresponding processing liquid discharge nozzle 51A. More specifically, as indicated by arrowed dotted lines in the drawing, the laser light is emitted toward the reflection member 513 provided at a (+R) side tip of the processing liquid discharge nozzle 51A. The laser light reflected on the reflection member 513 is received by the laser displacement meter 53A. By doing so, the position of the processing liquid discharge nozzle 51A, more specifically, a distance to the processing liquid discharge nozzle 51A viewed from the laser displacement meter 53A is determined.

An operator responsible for the adjusting operation rotates the adjusting nut 515 at the processing liquid discharge nozzle 51A on the basis of result of the measurement by the laser displacement meter 53A, thereby adjusting the nozzle position to an intended target position. In this way, it is possible to finely adjust the position of the processing liquid discharge nozzle 51A to adjust an etching width. The adjustment at this time can be made on the order of microns, for example.

Likewise, the laser displacement meter 53B emits laser light for distance measurement to the corresponding processing liquid discharge nozzle 51B and receives reflection of the laser light, thereby measuring the position of the processing liquid discharge nozzle 51B. The laser displacement meter 53C emits laser light for distance measurement to the corresponding processing liquid discharge nozzle 51C and receives reflection of the laser light, thereby measuring the position of the processing liquid discharge nozzle 51C. The operator can adjust the positions of the processing liquid discharge nozzles 51B and 51C finely using result of these measurements.

Each of the processing liquid discharge nozzles 51A to 51C is provided with the reflection member 513 having a reflection surface of a simple shape that is a planar surface pointed toward the laser displacement meter, for example. By causing laser light to enter the reflection member 513 and reflecting the laser light, it becomes possible to measure a distance reliably. Furthermore, providing the reflection member 513 of this configuration separately makes it possible to ensure a high degree of design freedom for the shape of the nozzle body 510 itself.

As for the laser displacement meter, it is possible to install only one for multiple nozzles by switching the nozzle to be measured for each nozzle position adjustment. However, providing the laser displacement meters 53A, 53B, and 53C individually for the processing liquid discharge nozzles 51A, 51B, and 51C respectively as described above achieves the following advantages. First, if the position of one nozzle deviates unintentionally during adjustment of the position of another nozzle, an operator can see the deviation and make correction properly. Furthermore, it is possible to set the location of each of the laser displacement meters 53A, 53B, and 53C with high accuracy and with excellent reproducibility, thereby achieving great accuracy also in the detection of the position of each nozzle. This case of providing only one laser displacement meter for a plurality of nozzles and the action and effect resulting from providing the laser displacement meters individually also apply to embodiments described later.

The laser measuring unit 53 is mounted temporarily for the adjusting operation and does not form a part of the processing unit 1 as a final product. Thus, increase in the number of installed laser displacement meters does not influence apparatus cost of the processing unit 1. Specifically, after implementation of the adjusting operation, the laser measuring unit 53 is removed. Mounting the nozzle block 50 and the laser measuring unit 53 at positions close to the maintenance opening 11d2 makes it possible to perform the operation of adjusting a nozzle position and perform the operation of mounting and removing the laser measuring unit 53 with excellent workability. These also apply to embodiments described later.

As described above, the processing unit 1 of the present embodiment corresponds to one embodiment of a “substrate processing apparatus” of the present invention. In the present embodiment, each of the processing liquid discharge nozzles 51A to 51C, specifically, the nozzle body 510 thereof corresponds to a “nozzle body” of the present invention, and the support mechanism 54 corresponds to a “support” of the present invention. The nozzle body and the support integrally function as a “nozzle mechanism” of the present invention. The large-diameter shaft part 51b of the nozzle body 510 corresponds to an “intermediate part” of the present invention. The axis of rotation AX corresponds to a “vertical axis” of the present invention.

The coil spring 514 functions as a “biasing part” of the present invention. The male screw part 51d and the adjusting nut 515 integrally function as a “position adjuster” of the present invention. The adjusting nut 515 corresponds to a “nut” of the present invention. The holding/rotating mechanism 2 functions as a “rotating mechanism” of the present invention. The nozzle support 57, particularly, the flange part 572 thereof functions as a “fixing member” of the present invention.

The present invention is not limited to the above-described embodiment but numerous modifications can be added to those described above without departing from the purport of the invention. For example, in the above-described embodiment, the nozzle body 510 has a substantially rod-like shape extending long in the moving radius direction

R in order to achieve the thinness of the nozzle block 50 by putting importance on the need of controlling the height of the processing unit 1 as described above. For this reason, the adjusting nut 515 is arranged closer to the center of the substrate S than the nozzle body 510.

This eventually creates a need for an operator to stretch a hand to a position beyond the nozzle head part 51a via the maintenance opening 11d1 for operating the adjusting nut 515 during the nozzle position adjustment. Instead of this, workability may be improved further by arranging the adjusting nut at a position below the nozzle head part and facing the maintenance opening 11d1 as described next, for example.

FIG. 12 shows a modification of the nozzle block. In describing a processing liquid discharge nozzle 51D of this modification by referring to FIG. 12, a structure corresponding to the structure of the processing liquid discharge nozzle 51A shown in FIG. 7A will be given the same sign and will not be described in detail. Some structures may have shapes different from those shown in FIG. 7A. These structures are also given the same signs as long as this is considered not to interfere with understanding.

In the configuration shown in FIG. 7A, the small-diameter shaft part 51c and the male screw part 51d are mounted on the (−R) side relative to the large-diameter shaft part 51b. Instead of this, at the processing liquid discharge nozzle 51D, an extending part 51e extending downward is provided at the bottom of the nozzle head part 51a. The extending part 51e is provided with a through hole 51f penetrating the extending part 51e in the R direction.

An extending part 543 extending downward is further provided at the base member 541 of the support mechanism 54. A shaft part 544 projects in the (+R) direction from a (+R) side surface of the extending part 543, and has a tip functioning as a male screw part 545. The shaft part 544 is passed through the inside of the coil spring 514. The coil spring 514 generates biasing force between the extending part 51e belonging to the nozzle body and the shaft part 544 belonging to the base member 541 acting in a direction of moving the extending part 51e and the shaft part 544 away from each other.

The male screw part 545 passes through the through hole 51f to make a projection projecting further than a (+R) side surface of the extending part 51e, and the adjusting nut 515 is mounted on this projection. This makes the adjusting nut 515 regulate a stationary position of the extending part 51e relative to the base member 541 against the biasing force from the coil spring 514. This stationary position is changed in the moving radius direction R by rotating the adjusting nut 515. Thus, it is possible to adjust an etching width by moving the position of the discharge port 511 provided at the top of the nozzle head part 51a in the moving radius direction R, like in the above-described embodiment. In this configuration, the adjusting nut 515 is located at a position facing the maintenance opening 11d1. This considerably improves workability of the adjusting operation by an operator. Meanwhile, this inevitably increases the entire height of the configuration compared to the configuration shown in FIG. 7A, causing a disadvantage in terms of thickness reduction of the apparatus. A configuration to be employed can be selected appropriately from these configurations in response to a purpose considered to be of greater importance.

As shown in FIG. 12, the structures for adjusting the position of the discharge port 511 in the moving radius direction R are arranged internal to the discharge port 511 to prevent these structures from going beyond the discharge port 511 externally. This achieves action and effect comparable to those of the embodiment described previously.

As another example, the processing unit 1 of the above-described embodiment is an apparatus that performs the bevel etching process by supplying the processing liquid toward the lower surface Sb of the peripheral edge part Ss of the substrate S. In addition to this, the present invention is further applicable to an apparatus that performs a bevel etching process on a top surface of the substrate S.

In the above-described embodiment, the groove formed at the base member 541 of the support mechanism 54 and conforming to the sectional shape of the large-diameter shaft part 51b of the nozzle body 510 functions as an “engagement part” of the present invention belonging to the support mechanism 54, and the pressure member 542 prevents the nozzle body 510 from coming off the base member 541. This configuration of supporting the nozzle body 510 using the groove-shape engagement part and the pressure member 542 in combination may be replaced with a configuration where a through hole having a shape conforming to the sectional shape of the large-diameter shaft part 51b is formed at the base member 541 and the nozzle body 510 is passed through this through hole.

In the processing unit 1 of the above-described embodiment, the nozzle block 50 includes the three processing liquid discharge nozzles 51A to 51C for discharging processing liquids different from each other. Meanwhile, the number of the nozzles to be provided is not limited to this but may be determined freely.

The configuration employed for the nozzle block 50 of the above-described embodiment allows implementation of the coarse adjusting mode and the fine adjusting mode for adjusting a nozzle position. Meanwhile, providing these two adjusting modes is not essential. A range of adjustment in the fine adjusting mode can be expanded by making the male screw part longer than that described above, for example.

As has been described above by giving the specific embodiment as an example, at the position adjuster in the substrate processing apparatus according to the present invention, for example, a male screw extending in the radial direction may be provided at one of the nozzle body and the support, a through hole for passage of the male screw may be formed at the other of the nozzle body and the support, and a nut to be threadedly engaged with the male screw may be provided further. In this configuration, rotating the nut makes it possible to change the positions of the nozzle body and the support relative to each other, thereby facilitating adjustment of the position of the nozzle body relative to the support. Furthermore, by employing position regulation using the nut and application of biasing force from the biasing part in cooperation with each other, it becomes possible to maintain the position of the nozzle body stably relative to the support.

In this case, the nozzle body may include the columnar intermediate part having a constant sectional shape in the radial direction, the nozzle head part connected to one end of the intermediate part in the radial direction and provided with the discharge port for discharge of the processing liquid, and the male screw part connected to the other end of the intermediate part in the radial direction and provided with the male screw. The support may be provided with a groove or a through hole as an engagement part belonging to the support (corresponding to an example of the “first engagement part” of the present invention) having a shape conforming to the sectional shape of the intermediate part. The intermediate part may be an engagement part belonging to the nozzle body (corresponding to an example of the “second engagement part” of the present invention).

In this configuration, the intermediate part of the nozzle body having the constant sectional shape in the radial direction and the groove or the through hole of the support as a counterpart of the intermediate part function as engagement parts and are engaged with each other. This allows the support to support the nozzle body movably in the radial direction of the substrate while allowing the support to regulate displacement of the nozzle body in the other directions.

In particular, if the shape of the intermediate part is a non-circular shape, the nozzle body is prevented from rotating unintentionally about an axis while being supported by the support, making it possible to suppress fluctuation in a direction of discharging the processing liquid.

As an example, scales may be formed at a regular angular interval at an outer periphery of the nut. The amount of rotation of the nut and the amount of displacement of the nozzle body are correlated to each other across the pitch of the male screw part.

Thus, by providing these scales at the nut, it becomes possible to visualize the amount of displacement of the nozzle body relative to the rotation of the nut, allowing the adjusting operation to be performed with improved convenience.

As an example, the nozzle body, the support, and the nut are preferably composed of resin. As these members arranged below the substrate are likely to be exposed to the processing liquid or a vapor atmosphere of the processing liquid, they are preferably composed of a resin material having high resistance to a chemical liquid. If these members are composed of metal, for example, fine powder may be caused by rubbing during adjustment of the nut and this may be a cause for contamination. Such a risk is reduced using a stable resin material having high chemical resistance.

As an example, the support may be mounted on the fixing member working independently of rotation of the substrate, and a position of mounting of the support on the fixing member may be changeable. In this configuration, changing the position of mounting of the support on the fixing member makes it possible to change the position of the nozzle body briefly relative to the substrate. For example, it is possible to expand a range of adjustment of the nozzle position and to achieve favorable accuracy in the adjustment by using coarse adjustment realized by this configuration and fine adjustment realized by the above-described position adjuster in combination.

In particular, if two or more nozzle bodies are supported by one support, changing a position of mounting of the support allows the nozzle bodies to be moved collectively.

Thus, it is possible to easily adjust the position of each nozzle body briefly.

In the above-described embodiment, the nozzle body is moved in the moving radius direction R for adjusting the discharge port. Meanwhile, the nozzle body may be moved in a tilted direction tilted from the moving radius direction R in a horizontal plane. At the nozzle block 50 of the above-described embodiment, an operator rotates the adjusting nut 515 to adjust the position of the processing liquid discharge nozzle 51, etc. Instead of this, the position adjuster may be configured to include a nozzle moving mechanism that locates the discharge port into position in the radial direction by driving the nozzle body in the radial direction using a driving source such as a stepping motor or a linear motor. The position adjuster may also be configured to include a nozzle moving mechanism that locates the discharge port into position in the radial direction by driving the nozzle body in a tilted direction tilted from the radial direction using the driving source. These embodiments make the position of the discharge port automatically adjustable by the action of the nozzle moving mechanism, so that the above-described problem in terms of workability does not occur.

An embodiment including the above-described nozzle moving mechanism (hereinafter called an “automatic adjustment type substrate processing apparatus”) will be described by referring to the drawings.

FIG. 13 shows the configuration and layout of a processing mechanism provided in an automatic adjustment type substrate processing apparatus corresponding to an example of a different embodiment of the substrate processing apparatus according to the present invention. In this embodiment, a processing mechanism 5 includes a nozzle block 50 arranged adjacent to a lower surface Sb of a substrate S, and a processing liquid supplier 59 that supplies a processing liquid to the nozzle block 50. The nozzle block 50 includes three processing liquid discharge nozzles 51A, 51B, and 51C each used for discharging the processing liquid, and a nozzle moving mechanism 58 that moves the processing liquid discharge nozzles 51A, 51B, and 51C independently of each other. As will be described later, the nozzle moving mechanism 58 moves the processing liquid discharge nozzles 51A to 51C independently of each other in the radial direction of the substrate S. By doing so, the position of each of the processing liquid discharge nozzles 51A to 51C relative to the substrate S (hereinafter called a “nozzle position”) is adjusted.

Like in the embodiment already described (hereinafter called the “preceding embodiment”), the processing liquid supplier 59 is connected to the three processing liquid discharge nozzles 51A to 51C. In the present embodiment, the nozzle block 50 is also mounted on a part of a peripheral edge part of a top surface of a flange part 572 in order to discharge the processing liquid toward a peripheral edge part of the lower surface Sb of the substrate S.

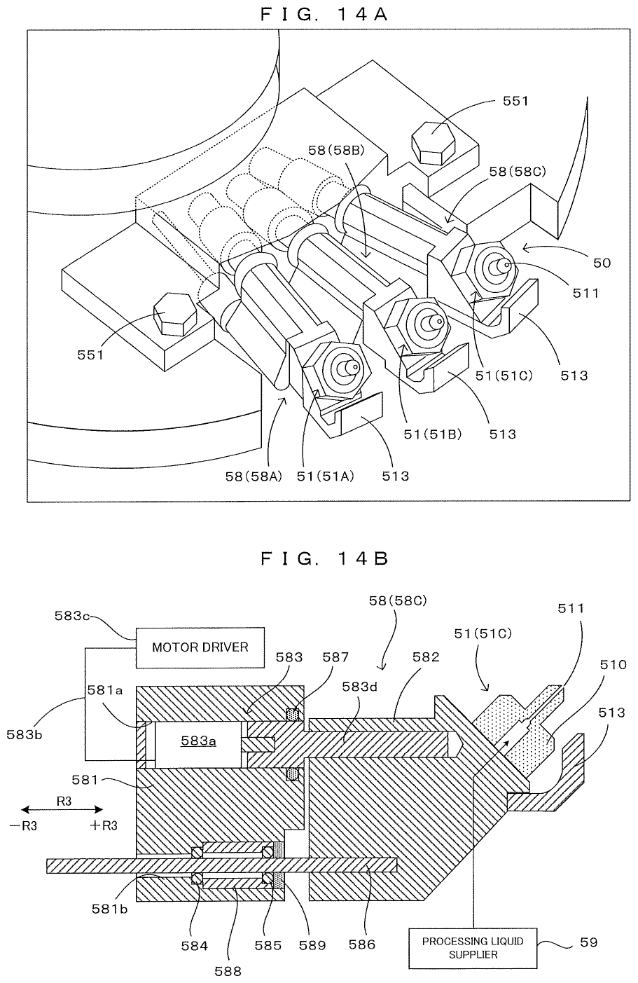

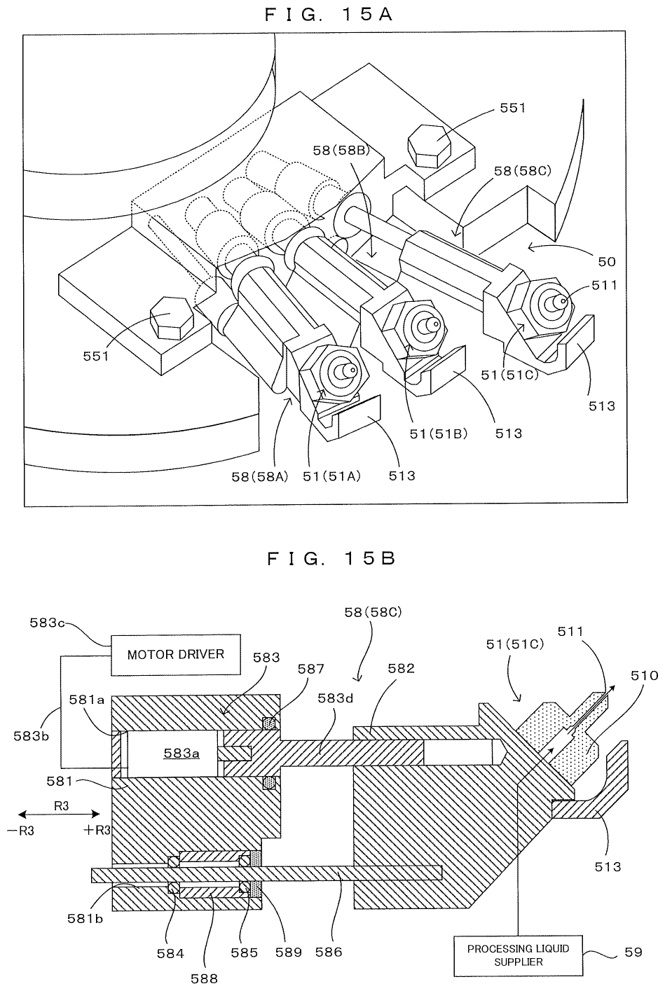

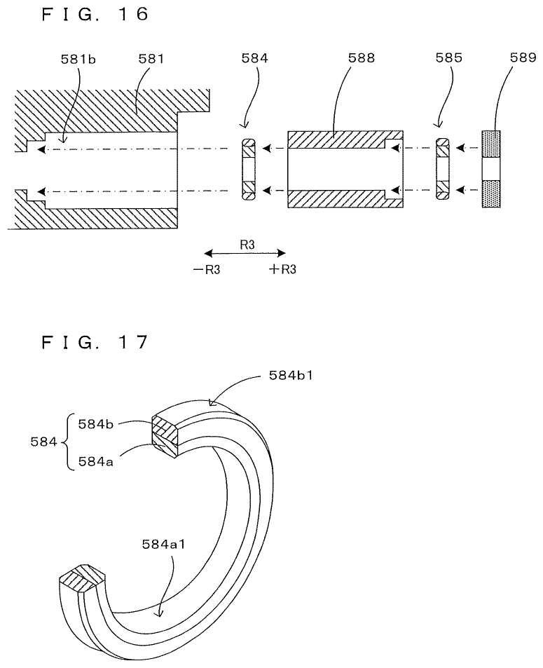

FIGS. 14A, 14B, 15A, and 15B show the configurations of the processing liquid discharge nozzle and the nozzle moving mechanism. Of these drawings, FIGS. 14A and 14B show an entirely retreating state where all the processing liquid discharge nozzles retreat. FIG. 14A is a perspective view showing the configurations of the processing liquid discharge nozzles and the nozzle moving mechanism in the entirely retreating state. FIG. 14B shows sectional configurations of the processing liquid discharge nozzle and the nozzle moving mechanism in the entirely retreating state. FIGS. 15A and 15B show a partially advancing state where only one of the processing liquid discharge nozzles advances. FIG. 15A is a perspective view showing the configurations of the processing liquid discharge nozzles and the nozzle moving mechanism in the partially advancing state. FIG. 15B shows sectional configurations of the advancing processing liquid discharge nozzle and the nozzle moving mechanism.

As shown in FIG. 13, the nozzle block 50 is mounted on the flange part 572 having a substantially annular shape provided at the top of a nozzle support 57. The nozzle block 50 includes the nozzle moving mechanism 58 provided for each of the processing liquid discharge nozzles 51A to 51C. In the following, if three nozzle moving mechanisms for moving corresponding ones of the processing liquid discharge nozzles 51A to 51C in moving radius directions R1 to R3 respectively are to be called collectively, these nozzle moving mechanism will be called a “nozzle moving mechanism 58.” Meanwhile, if the three nozzle moving mechanism are to be called individually, a nozzle moving mechanism for the processing liquid discharge nozzle 51A will be called a “nozzle moving mechanism 58A,” a nozzle moving mechanism for the processing liquid discharge nozzle 51B will be called a “nozzle moving mechanism 58B,” and a nozzle moving mechanism for the processing liquid discharge nozzle 51C will be called a “nozzle moving mechanism 58C.”

The three nozzle moving mechanisms 58A to 58C basically have the same configuration except that they move the corresponding nozzles in the moving radius directions R1 to R3 respectively. The processing liquid discharge nozzles 51A to 51C have the same shape. Then, in the present specification, one processing liquid discharge nozzle 51C and the corresponding nozzle moving mechanism 58C will be described in this order. Common structures of the other discharge nozzles 51A and 51B and those of the other nozzle moving mechanisms 58A and 58B will be given the same or corresponding signs and will not be described.

The configuration of the processing liquid discharge nozzle 51C will be described by referring to FIGS. 14A, 14B, 15A, and 15B. A nozzle body 510 forming a principal part of the processing liquid discharge nozzle 51C is configured to be mountable on and removable from a nozzle head part 582 of the nozzle moving mechanism 58C. The nozzle body 510 has a tip where a discharge port 511 for discharge of a processing liquid is provided. The processing liquid supplied from the processing liquid supplier 59 is discharged from the discharge port 511 diagonally upward at an elevation angle of 45 degrees and outward as viewed from an axis of rotation AX. The processing liquid is discharged toward a lower surface peripheral edge part Ss of the substrate S. The processing liquid discharge nozzle 51 (51A to 51C) is composed of a material having excellent chemical resistance such as a resin material, for example. As an example, a material to be used is suitably selectable from a polyethylene resin, a polytetrafluoroethylene (PTFE) resin, and a polyetheretherketone (PEEK) resin in response to a purpose.

If a metallic thin film or a thin film of a metallic compound is formed on the lower surface Sb of the substrate S and the discharged processing liquid has solubility in this coating film, the thin film on the substrate lower surface Sb is removed by etching in a region where the processing liquid has landed. If the substrate S rotates, the processing liquid is spread externally from the liquid landing position by the action of centrifugal force. As a result, the thin film external to the liquid landing position is removed.

The nozzle head part 582 has a (+R3) side end mounted with a reflection member 513 having a (+R3) side end surface functioning as a planar reflection surface. The reflection member 513 is used in measuring a nozzle position using a laser displacement meter, for example, and achieves accurate and stable position measurement by reflecting laser light emitted from the laser displacement meter.

The configuration and motion of the nozzle moving mechanism 58C will be described next. The nozzle moving mechanism 58C includes a fixed support 581, the nozzle head part 582, a nozzle driver 583, glide rings 584 and 585 in a pair, and a guide shaft 586. Of these members, the fixed support 581, the nozzle head part 582, and the nozzle driver 583 (except a motor 583a and a wiring 583b described later) can be composed using a material such as a polyethylene resin suitably selected in response to a purpose, like the processing liquid discharge nozzle 51. The guide shaft 586 can be composed of a material prepared by coating a stainless steel rod member with PTFE.

The fixed support 581 corresponds to an example of the “support” of the present invention and is fixedly provided on the flange part 572 of the nozzle support 57. The fixed support 581 has an upper end and a lower end where a through hole 581a and a through hole 581b extending in the moving radius direction R3 are provided respectively.

With the motor 583a in a posture of pointing a rotary axis thereof toward the nozzle head part 582, the motor 583a as a driving source of the nozzle driver 583 is inserted in the through hole 581a. The motor 583a is connected to a motor driver 583c via the wiring 583b coated with a fluorine shrinkable tube. The through hole 581a has an opening closer to a (−R3) direction that is sealed with a caulking agent, for example, except in a part where the wiring 583b is provided.

The nozzle driver 583 includes a shaft member 583d having a (−R3) side end connected to the above-described rotary axis in the through hole 581a. A glide ring 587 is mounted adjacent to an opening of the through hole 581a closer to the (+R) direction to support the shaft member 583d rotatably about an axis of rotation of the rotary axis. The configuration of the glide ring 587 will be described later.

An outer peripheral surface of the shaft member 583d is provided with a male screw in a part closer to the (+R3) direction than the glide ring 587 and the male screw functions as a male screw part. The male screw part is threadedly engaged with a female screw part provided at the nozzle head part 582. Thus, if the control unit 10 applies a nozzle moving command to the motor driver 583c, the motor driver 583c rotates the rotary axis of the motor 583a in response to the command. In response to a direction of this rotation and the amount of this rotation, the nozzle head part 582, and the processing liquid discharge nozzle 51C and the reflection member 513 mounted on a (+R3) side end of the nozzle head part 582 integrally move reciprocally in the moving radius direction R3. For example, rotation of the above-described rotation axis in a positive direction moves these members including the nozzle head part 582 from positions shown in FIGS. 14A and 14B to positions shown in FIGS. 15A and 15B. Conversely, rotation of this rotation axis in a negative direction moves these members including the nozzle head part 582 in the opposite direction.

As described above, the motor 583a is used as an example of an “actuator” of the present invention to move the processing liquid discharge nozzle 51C in the moving radius direction R3. However, merely doing so fails to provide stability in positioning of the processing liquid discharge nozzle 51C. In this regard, in the present embodiment, the glide rings 584 and 585 in a pair and the guide shaft 586 are added as principal structures of a guide mechanism to guide movement of the processing liquid discharge nozzle 51C in the moving radius direction R3. More specifically, the following configuration is provided.

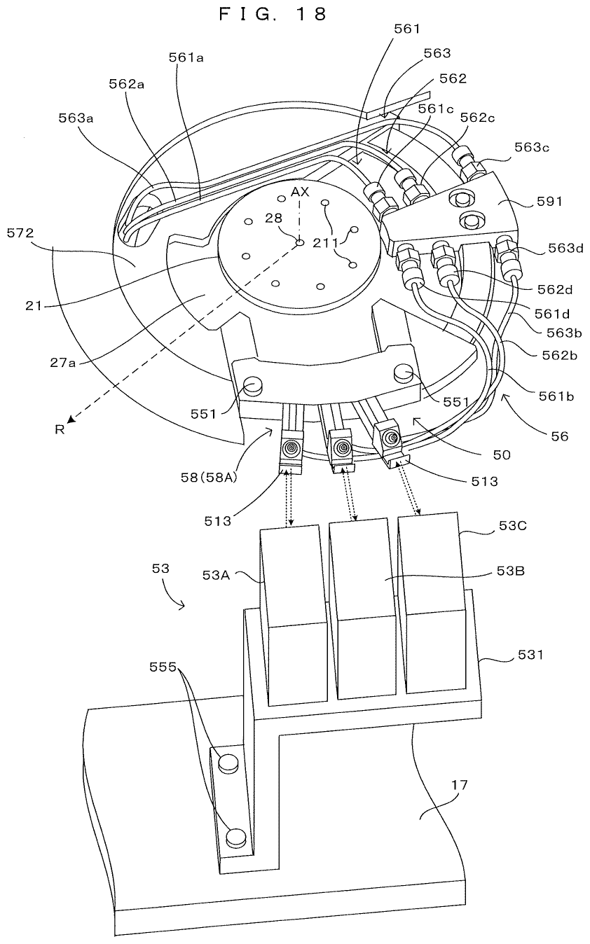

FIG. 16 is an exploded assembly view showing a method of fitting the glide rings in a pair to the fixed support. As shown in FIG. 16, the through hole 581b formed at the lower end of the fixed support 581 has an inner diameter increased further as the through hole 581b extends closer to the (+R3) direction from the (−R3) direction. As a result, two steps are formed inside the through hole 581b. In the thinnest region in the through hole 581b, namely, in a through region closest to the (−R3) direction (hereinafter called a “counter-head side through region”), the inner diameter of the through hole 581b is slightly larger than the outer diameter of the guide shaft 586. In a through region (hereinafter called an “intermediate through region”) next to the counter-head side through region and closer to the (+R3) direction than the counter-head side through region, the inner diameter is larger than the inner diameter in the counter-head side through region and equal to or slightly smaller than the outer diameters of the glide rings 584 and 585. In a through region (hereinafter called a “head-side through region”) next to the intermediate through region and closer to the (+R3) direction than the intermediate through region, the inner diameter is larger than the inner diameter in the intermediate through region and equal to the outer diameters of spacers 588 and 589. This allows the spacers 588 and 589 to be inserted into the head-side through region.

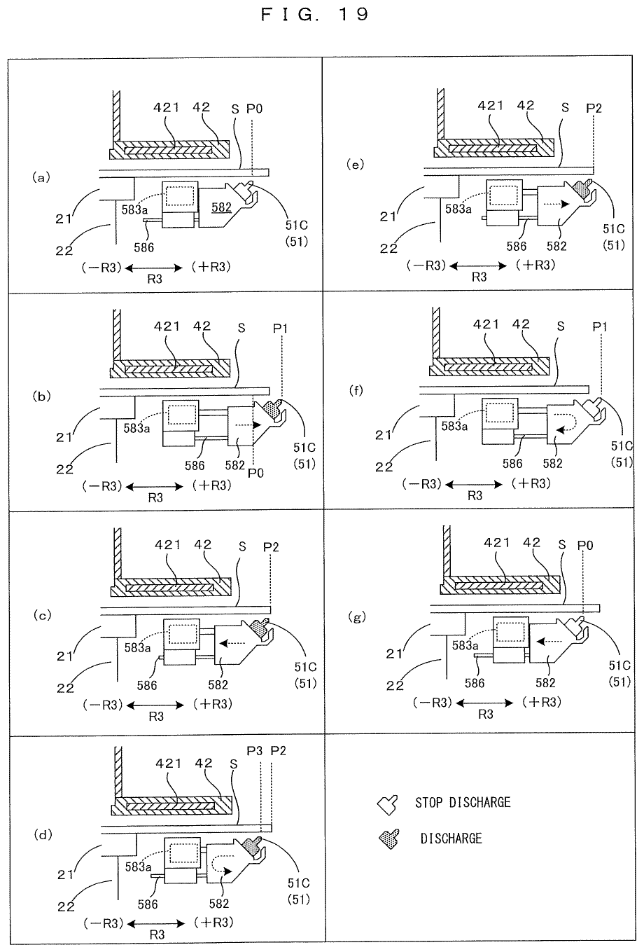

FIG. 17 shows the configuration of the glide ring. The glide ring 584 has an integrated shape including a first ring member composed of a resin material having both chemical resistance to the processing liquid and water resistance, and the second ring member composed of an elastic material having both the chemical resistance and the water resistance. The glide ring 584 is a seal ring entirely finished into a ring shape. More specifically, the glide ring 584 includes a ring-shaped resin member (first ring member) 584a having an inner diameter equal to the outer diameter of the guide shaft 586, and a ring-shaped elastic member (second ring member) 584b having an outer diameter equal to or slightly larger than the inner diameter of the intermediate through region. The ring-shaped elastic member 584b is fitted externally to the ring-shaped resin member 584a. Thus, at the glide ring 584, an inner peripheral surface 584a1 of the ring-shaped resin member 584a functions as a ring-shaped slidable contact part in slidable contact along an entire perimeter with an outer peripheral surface of the guide shaft 586. Furthermore, an outer peripheral surface 584b1 of the ring-shaped elastic member 584b functions as a ring-shaped tight contact part in tight contact along an entire perimeter with an inner peripheral surface of the intermediate through region. The glide ring 585 has a configuration completely the same as that of the glide ring 584. As will be described next, the glide ring 585 is separated in the (+R3) direction from the glide ring 584 by the spacer 588 by a certain distance.

As shown in FIG. 16, the spacers 588 and 589 each have a cylindrical shape insertable into the head-side through region. The spacer 588 is provided with a through hole having through regions of inner diameters different from each other. One of the through regions is a (−R3) side through region extending from the (−R3) direction to a position by a distance corresponding to a spacing distance between the glide rings 584 and 585. The other through region is a (+R3) side through region extending from the (−R3) side through region toward the (+R3) direction by a distance corresponding to the thickness of the glide ring 585. The other spacer 589 has a ring shape having an inner diameter slightly larger than the outer diameter of the guide shaft 586.

As shown in FIG. 16, the glide ring 584, the spacer 588, the glide ring 585, and the spacer 589 are inserted in this order into the through hole 581b from the (+R3) direction toward the (−R3) direction. The glide ring 584 is inserted in the intermediate through region in the through hole 581b and is locked at the step formed between the intermediate through region and the counter-head side through region. Furthermore, the glide ring 584 is caught between this step and the spacer 588 in the moving radius direction R3 to be located into position in the through hole 581b.

The glide ring 585 is inserted into the (+R3) side through region of the spacer 588 inserted in the head-side through region. Then, the spacer 589 is inserted into the head-side through region. As a result, the glide ring 585 is caught between a step formed between the (+R3) side through region and the (−R3) side through region and the spacer 589 in the moving radius direction R3 to be located into position in the through hole 581b. In this way, the glide rings 584 and 585 in a pair are separated from each other by a distance corresponding to the length of the (−R3) side through region in the moving radius direction R3.

As described above, by the insertion of the glide ring 584, the spacer 588, the glide ring 585, and the spacer 589, the glide rings 584 and 585 are fitted to the fixed support 581. Then, a (−R3) side end of the guide shaft 586 is inserted into the glide rings 584 and 585 in a pair in a manner allowing slidable contact with the glide rings 584 and 585. More specifically, the outer peripheral surface of the guide shaft 586 is supported along an entire perimeter while slidably contacting the ring-shaped slidable contact parts of the glide rings 584 and 585. The guide shaft 586 has a (+R3) side end that is press-fitted in a hole formed in advance at the nozzle head part 582 to be fixed to the nozzle head part 582. Thus, while the (−R3) side end of the guide shaft 586 extends to the through hole 581b in the moving radius direction R3, the guide shaft 586 moves in the moving radius direction R3 integrally with the processing liquid discharge nozzle 51C and the nozzle head part 582. In addition, the (−R3) side end of the guide shaft 586 is always supported by the glide rings 584 and 585 in a pair in a manner slidable in the moving radius direction R3. As a result, the processing liquid discharge nozzle 51C moves stably in the moving radius direction R3 to locate the processing liquid discharge nozzle 51C into position with high accuracy.

The outer peripheral surface (ring-shaped tight contact part) of the glide ring 584 tightly contacts the fixed support 581 directly, and the outer peripheral surface (ring-shaped tight contact part) of the glide ring 585 tightly contacts the fixed support 581 across the spacer 588. Specifically, each of the glide rings 584 and 585 is interposed between the outer peripheral surface of the guide shaft 586 and the inner peripheral surface of the through hole 581b to seal a ring-shaped space between the guide shaft 586 and the through hole 581b. As a result, it is possible to effectively prevent the processing liquid from flowing into the ring-shaped space.

This sealing effect is also achieved in the through hole 581a by providing the glide ring 587 at the through hole 581a. As shown in FIGS. 14B and 15B, in the present embodiment, an annular groove is formed in the vicinity of a (+R3) side opening of the through hole 581a, and the glide ring 587 is inserted in this groove. The glide ring 587 is configured in the same way as the glide rings 584 and 585. Specifically, the glide ring 587 includes a ring-shaped resin member (first ring member) having an inner diameter equal to the outer diameter of the (−R3) side end of the shaft member 583d, and a ring-shaped elastic member (second ring member) having an outer diameter equal to or slightly larger than the inner diameter of the through hole 581a (FIG. 16). The ring-shaped elastic member is fitted externally to the ring-shaped resin member. Thus, as a result of insertion of the glide ring 587 into the groove, an inner peripheral surface of the ring-shaped resin member functions as a ring-shaped slidable contact part in slidable contact along an entire perimeter with an outer peripheral surface of the (−R3) side end of the shaft member 583d. Furthermore, an outer peripheral surface of the ring-shaped elastic member functions as a ring-shaped tight contact part in tight contact along an entire perimeter with an inner peripheral surface of the groove. Specifically, the glide ring 587 is interposed between the outer peripheral surface of the shaft member 583d and an inner peripheral surface of the through hole 581a to seal a ring-shaped space between the shaft member 583d and the through hole 581a. As a result, it is possible to effectively prevent the processing liquid from flowing into the ring-shaped space, allowing the nozzle to be located into position with high accuracy without being influenced by the processing liquid.

The nozzle moving mechanism 58C described above is to move the processing liquid discharge nozzle 51C in the moving radius direction R3. The other nozzle moving mechanisms 58A and 58B are configured in the same way. Thus, the nozzles can also be located into position with high accuracy without being influenced by the processing liquid. This will be described supplementarily. In the substrate processing apparatus after assembly or before start of use of the apparatus after component replacement, it is necessary to perform an operation of adjusting a nozzle position in order to obtain a predetermined etching width. Meanwhile, the etching width required in the process is not always constant but may be changed according to a purpose. For a purpose such as size reduction of a device or improvement of a yield, accuracy required for the adjustment of the nozzle position is being increased in recent years. For example, the adjustment is required to be made on the order of several tens of microns. In order to realize such adjustment, the nozzle moving mechanisms 58A to 58C for stabilizing nozzle movement are required to be provided below the substrate S.

Subjected to the layout condition that the nozzle moving mechanisms 58A to 58C be provided below the substrate S, the following point is required to be considered. Under this layout condition, the processing liquid discharged from the nozzle is supplied to the lower surface peripheral edge part of the substrate S. Then, part of the processing liquid drops to the nozzle moving mechanisms 58A to 58C. Specifically, the nozzle moving mechanisms 58A to 58C are exposed to an atmosphere of the processing liquid. This creates a desire for the nozzle moving mechanisms 58A to 58C capable of moving the nozzles stably even in the processing liquid atmosphere. However, a nozzle moving mechanism fulfilling this desire has yet to be provided, failing to locate the nozzle into position with high accuracy in the processing liquid atmosphere.

In this regard, in the present embodiment, the nozzle block 50 includes the three processing liquid discharge nozzles 51A, 51B, and 51C each used for discharging the processing liquid (FIGS. 14A, 14B), and the nozzle moving mechanism 58 that moves the processing liquid discharge nozzles 51A, 51B, and 51C independently of each other. As will be described later, the nozzle moving mechanism 58 moves the processing liquid discharge nozzles 51A to 51C independently of each other in the radial direction of the substrate. By doing so, the position of each of the processing liquid discharge nozzles 51A to 51C relative to the substrate S (hereinafter called a “nozzle position”) is adjusted.

In this way, in the substrate processing apparatus of the present embodiment where the nozzle is moved to be located into position below the substrate S, it is possible to achieve positioning of the nozzle with high accuracy without being influenced by the processing liquid.

The seal ring of the present embodiment is such that the ring-shaped slidable contact part is in slidable contact along an entire perimeter with the outer peripheral surface of the guide shaft and the ring-shaped tight contact part is in tight contact along an entire perimeter with the inner peripheral surface of the through hole. Meanwhile, a relationship between the slidable contact and the tight contact may be reversed. Specifically, the seal ring may be configured in such a manner that the ring-shaped slidable contact part is in slidable contact along an entire perimeter with the inner peripheral surface of the through hole and the ring-shaped tight contact part is in tight contact along an entire perimeter with the outer peripheral surface of the guide shaft.

In the present embodiment, the structures for adjusting the position of the discharge port 511 in the moving radius direction R, specifically, the structures for adjusting the nozzle position are arranged internal to the discharge port 511 to prevent these structures from going beyond the discharge port 511 externally. Furthermore, in the present embodiment, the discharge port 511 is provided in such a manner that the processing liquid is discharged diagonally upward at an elevation angle of 45 degrees and outward as viewed from the axis of rotation AX. This makes it possible to suppress a planar size while realizing the mode of adjusting the nozzle position automatically, thereby allowing downsizing of the substrate processing apparatus 1. As a result, it is possible to reduce the usage of gas in the substrate processing apparatus 1 to allow reduction in environmental load.

Furthermore, in the present embodiment, the rotating cup 31 rotates about the axis of rotation AX while surrounding the outer periphery of the rotating substrate S and collects droplets of the processing liquid scattered from the substrate S. This makes it difficult to arrange all or some of the structures for adjusting the position of the discharge port 511 external to the discharge port 511 in the moving radius direction R. In this regard, in the substrate processing apparatus 1 having the above-described configuration, it is possible to provide both the rotating cup 31 and adjustment of the positions of the processing liquid discharge nozzles 51A to 51C independent of each other.

The description will be continued by referring back to FIG. 13. A pipe 56 for supplying the processing liquids to the processing liquid discharge nozzles 51A to 51C has an arrangement similar to that of the preceding embodiment. In FIG. 13, a sign 561 represents a pipe for supplying an SC1 liquid to the processing liquid discharge nozzle 51A, a sign 562 represents a pipe for supplying DHF to the processing liquid discharge nozzle 51B, and a sign 563 represents a pipe for supplying functional water (CO2 water) to the processing liquid discharge nozzle 51C.

Described next is an operation of adjusting a nozzle position in a processing unit 1 having the above-described configuration. A nozzle position is required to be adjusted prior to implementation of the bevel process of removing a thin film from the peripheral edge part Ss of the substrate S in order to achieve a target etching width. The reason for this is that, as described above, an etching width is determined by a liquid landing position of the processing liquid from the nozzle and the liquid landing position is influenced by the nozzle position.

The operation of adjusting the nozzle position may be performed as follows, for example. First, with the processing liquid discharge nozzles 51A to 51C mounted on the nozzle moving mechanism 58 of the nozzle block 50, the nozzle block 50 is mounted on the flange part 572 with a fastening member 551. The position of each of the processing liquid discharge nozzles 51A to 51C is adjusted in an automatic adjusting mode. For example, the position of each of the processing liquid discharge nozzles 51A to 51C can be adjusted finely as follows, for example.

FIG. 18 schematically shows nozzle position adjustment in the automatic adjusting mode. In the automatic adjusting mode, a laser measuring unit 53 same as that used in the preceding embodiment is introduced. A female screw for fixing a support frame 531 is formed in advance at a base member 17, and the support frame 531 is fixed to the base member 17 using a fastening member 555 as needed. By doing so, it becomes possible to locate laser displacement meters 53A, 53B, and 53C at respective appropriate positions corresponding to the three processing liquid discharge nozzles 51A, 51B, and 51C respectively.

The laser displacement meter 53A emits laser light for distance measurement to the corresponding processing liquid discharge nozzle 51A. More specifically, as indicated by arrowed dotted lines in the drawing, the laser light is emitted toward the reflection member 513 provided at a (+R) side tip of the processing liquid discharge nozzle 51A. The laser light reflected on the reflection member 513 is received by the laser displacement meter 53A. By doing so, the position of the processing liquid discharge nozzle 51A, more specifically, a distance to the processing liquid discharge nozzle 51A viewed from the laser displacement meter 53A is determined.

In response to result of the measurement by the laser displacement meter 53A and an etching width, the arithmetic processor 10A applies a nozzle moving command to a motor driver 583c, thereby adjusting the nozzle position to an intended target position. In this way, it is possible to adjust the position of the processing liquid discharge nozzle 51A to adjust the etching width. The adjustment at this time can be made on the order of microns, for example.

Likewise, the laser displacement meter 53B emits laser light for distance measurement to the corresponding processing liquid discharge nozzle 51B and receives reflection of the laser light, thereby measuring the position of the processing liquid discharge nozzle 51B. The laser displacement meter 53C emits laser light for distance measurement to the corresponding processing liquid discharge nozzle 51C and receives reflection of the laser light, thereby measuring the position of the processing liquid discharge nozzle 51C. Using result of these measurements and the etching width, the arithmetic processor 10A adjusts the positions of the processing liquid discharge nozzles 51B and 51C.

Each of the processing liquid discharge nozzles 51A to 51C is provided with the reflection member 513 having a reflection surface of a simple shape that is a planar surface pointed toward the laser displacement meter, for example. By causing laser light to enter the reflection member 513 and reflecting the laser light, it becomes possible to measure a distance reliably. Furthermore, providing the reflection member 513 of this configuration separately makes it possible to ensure a high degree of design freedom for the shape of the nozzle body 510 itself.

As described above, according to the different embodiment (automatic adjustment type substrate processing apparatus), the moving radius directions R1 to R3 correspond to a “nozzle moving direction” of the present invention. The through hole 581b corresponds to an example of a “through hole” of the present invention. The glide rings 584 and 585 correspond to examples of “seal rings in a pair” of the present invention. The nozzle head part 582 corresponds to a “movable support” of the present invention.

In the above-described different embodiment, the glide ring used as the “seal ring” of the present invention is composed of the two types of ring members in combination. However, the seal ring is not limited to this. For example, a member to be used as the “seal ring” of the present invention may be a single ring member having an inner peripheral surface functioning as a ring-shaped slidable contact part, and an outer peripheral surface functioning as a ring-shaped tight contact part. Alternatively, the seal ring to be used may be composed of a combination of three or more types of ring members.

In the above-described different embodiment, the processing liquid discharge nozzle 51 (51A, 51B, 51C) is coupled to the nozzle driver 583 and the guide shaft 586 indirectly across the nozzle head part 582 (movable support). Meanwhile, these members may be coupled to each other directly.

In the above-described different embodiment, the motor 583a is used as an example of the “actuator” of the present invention. Meanwhile, a driving component such as a card motor may be used as the “actuator” of the present invention, for example.

In the above-described different embodiment, the processing liquid discharge nozzle 51 (51A, 51B, 51C) is moved in the moving radius direction R (R1 to R3). However, the nozzle moving direction is not limited to this. Specifically, the present invention is further applicable to a substrate processing apparatus where the processing liquid discharge nozzle 51 is moved in a direction tilted from the radial direction of the substrate S (moving radius direction R) within a horizontal plane.

In the processing unit 1 of the above-described different embodiment, the nozzle block 50 includes the three processing liquid discharge nozzles 51A to 51C for discharging processing liquids different from each other. Meanwhile, the number of the nozzles to be provided is not limited to this but may be determined freely.

In the above-described different embodiment, the nozzle is reciprocally movable in the nozzle moving direction. This makes the following configuration further applicable where the processing liquid is supplied to the lower surface peripheral edge part of the substrate S in a scan-in/scan-out system.

FIG. 19 schematically shows the configuration and motion of a nozzle mover. FIGS. 19(a) and 19(g) are schematic views showing a home position. FIGS. 19(b) and 19(f) are schematic views showing a pre-dispense position. FIGS. 19(c) and 19(e) are schematic views showing a pre-dispense position. FIG. 19(d) is a schematic view showing a maximum processing position. In these drawings, to clearly illustrate the processing liquid discharge nozzle 51 from which the processing liquid is being discharged, this processing liquid discharge nozzle 51 is shown with dots. Meanwhile, the processing liquid discharge nozzle 51 from which discharge of the processing liquid is stopped is shown without dots. Furthermore, arrowed dotted lines in these drawings show directions of moving the processing liquid discharge nozzle 51. In the exemplary case described herein, the processing liquid is supplied while the processing liquid discharge nozzle 51C is caused to make scan-in and scan-out motions. This basically applies to the processing liquid discharge nozzles 51A and 51B.

Before implementation of the bevel process on the substrate S, the control unit 10 checks to see that all the processing liquid discharge nozzles 51A to 51C are at a home position P0. At this time, if some or all of the processing liquid discharge nozzles 51 are not at the home position P0, these processing liquid discharge nozzles 51 are moved to the home position P0 in response to a home returning command from the control unit 10. Then, with all the processing liquid discharge nozzles 51 at the home position P0 as shown in FIG. 19(a), the processing liquid discharge nozzle 51 (here, nozzle 51C) to discharge the processing liquid to be supplied makes the following motions sequentially. Specifically, the following motions A to H are made in the order given below.

Motion A: Outward movement from the home position P0 to a pre-dispense position P1 (see an arrowed dotted line in FIG. 19(b)).

Motion B: Start discharge of the processing liquid at the pre-dispense position P1 (see dots in FIG. 19(b)).

Motion C: Return movement from the pre-dispense position P1 to a maximum processing position P3 via an end surface position P2 while discharge of the processing liquid continues (see an arrowed dotted line in FIG. 19(c)).

Motion D: Reversing movement at the maximum processing position P3 while discharge of the processing liquid continues (see an arrowed dotted line in FIG. 19(d)).

Motion E: Outward movement from the maximum processing position P3 to the pre-dispense position P1 via the end surface position P2 while discharge of the processing liquid continues (see an arrowed dotted line in FIG. 19(e)).

Motion F: Stop discharge of the processing liquid at a moment of passage through the end surface position P2 (see the absence of dots in FIG. 19(f)).

Motion G: Reversing movement at the pre-dispense position P1 while stop of discharge of the processing liquid continues (see an arrowed dotted line in FIG. 19(f)). Motion H: Movement to and stop at the home position P0 while stop of discharge of the processing liquid continues (see an arrowed dotted line in FIG. 19(g)).

During the foregoing motions, specifically, during the motion C, a so-called scan-in motion is made by which the discharge port 511 of the processing liquid discharge nozzle 51C passes through the end surface position P2 to go into a place below the substrate S while discharge of the processing liquid continues. During the motion D, a moving direction of the processing liquid discharge nozzle 51C is reversed while supply of the processing liquid to the maximum processing position P3 continues. During the motion E, a so-called scan-out motion is made by which the discharge port 511 of the processing liquid discharge nozzle 51C passes through the end surface position P2 to go out of the place below the substrate S while discharge of the processing liquid continues.

In one configuration, if the substrate S is given a notch, control may be exerted in terms of the following control items in response to the position of the notch.

Opening and closing of a liquid discharge valve (not shown) provided at the processing liquid supplier 59.

Control over the position of the processing liquid discharge nozzle 51C in the moving radius direction R3.

Nozzle moving speed of the processing liquid discharge nozzle 51C.

The number of rotations of the substrate S.

The amount of discharge (hereinafter also called a “discharge flow rate”) of a selected processing liquid per unit time from the processing liquid discharge nozzle 51C. Exerting control under these items reduces the amount of the processing liquid to reach the notch, specifically, the amount to reach at a cutout, making it possible to reduce the amount of liquid splash during the bevel process.

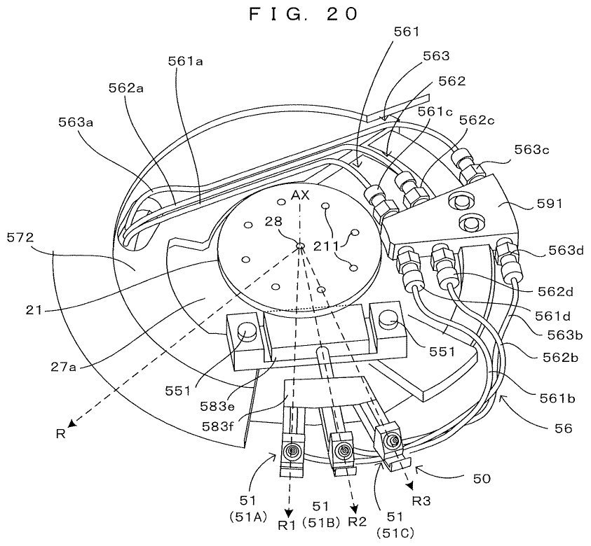

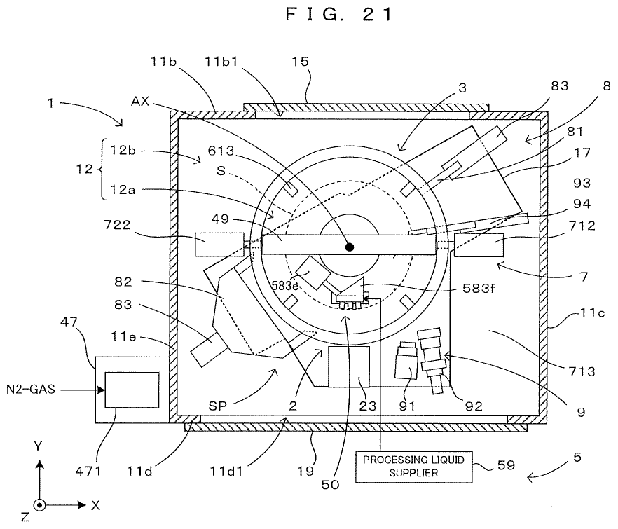

The automatic adjustment type substrate processing apparatus is configured to move a plurality of the processing liquid discharge nozzles 51 individually. Meanwhile, in one configuration, the processing liquid discharge nozzles 51 may be moved collectively, as shown in FIG. 20 or 21.

FIG. 20 shows the configuration and layout of a processing mechanism provided in an automatic adjustment type substrate processing apparatus corresponding to an example of a different embodiment of the substrate processing apparatus according to the present invention. In the present embodiment, the fastening members 551, 551 such as screws are passed through opposite ends of the base member 541. The fastening members 551, 551 are threadedly engaged with screw holes formed at the flange part 572, thereby fixing the base member 541 to the flange part 572. Furthermore, a card motor 583e is mounted on the base member 541 from above. A support 583f supporting the three processing liquid discharge nozzles 51 is mounted on a drive axis of the card motor 583e. The support 583f is provided movably in the moving radius direction R. Thus, if a nozzle moving command is applied from the control unit 10 to the motor driver 583c, the motor driver 583c drives the motor 583e in response to the command to move the support 583f in the moving radius direction R with the three processing liquid discharge nozzles 51 supported collectively. As a result, it becomes possible to adjust the nozzle positions collectively.

FIG. 21 shows the configuration and layout of a processing mechanism provided in an automatic adjustment type substrate processing apparatus corresponding to an example of a still different embodiment of the substrate processing apparatus according to the present invention. The present embodiment largely differs from the embodiment shown in FIG. 20 in the layout of the card motor 583e, the support 583f, and the processing liquid discharge nozzle 51. Specifically, in the apparatus shown in FIG. 20, these members are arranged linearly in the moving radius direction R. Hence, depending on a dimensional relationship between the members of the apparatus, it may be difficult to arrange the card motor 583e according to the foregoing layout. By contrast, as shown in

FIG. 21, the card motor 583e is arranged at a position deviating from the moving radius direction R of the processing liquid discharge nozzle 51. By doing so, force is applied from the card motor 583e to the support 583f in a direction tilted from the moving radius direction R in a horizontal plane. In this regard, the support 583f is configured to move in the moving radius direction R in response to receipt of the force. Thus, if a nozzle moving command is applied from the control unit 10 to the motor driver 583c, the motor driver 583c drives the motor 583e in response to the command to move the support 583f in the moving radius direction R with the three processing liquid discharge nozzles 51 supported collectively. As a result, it becomes possible to adjust the nozzle positions collectively. Employing this configuration achieves an increased degree of design freedom.

Although the present invention has been described with reference to specific embodiments, this description is not meant to be construed in a limiting sense. Various modifications of the disclosed embodiment, as well as other embodiments of the present invention, will become apparent to persons skilled in the art upon reference to the description of the present invention. It is therefore contemplated that the appended claims will cover any such modifications or embodiments as fall within the true scope of the present invention.

The present invention is applicable to a substrate processing apparatus in general that processes a peripheral edge part of a substrate by supplying a processing liquid to the peripheral edge part from a nozzle arranged below the substrate.

What is claimed is:

1. A substrate processing apparatus comprising:
a rotating mechanism configured to hold a circular substrate in a horizontal posture and rotates the substrate about a vertical axis passing through a center of the substrate; and
a nozzle mechanism including a nozzle body, a support and a position adjuster, the nozzle body being arranged below the substrate and having a discharge port from which a processing liquid is discharged toward a lower surface peripheral edge part of the substrate, the support being configured to support the nozzle body in a manner that makes the position of the discharge port changeable in a radial direction of the substrate, the position adjuster being configured to adjust the position of the discharge port by moving the nozzle body relative to the support, wherein
the support and the position adjuster are arranged internal to a virtual arc centered on the vertical axis and passing through the discharge port.

2. The substrate processing apparatus according to claim 1, wherein
the support is configured to support the nozzle body movably in the radial direction, and
the position adjuster is configured to adjust the position of the discharge port by moving the nozzle body in the radial direction.

3. The substrate processing apparatus according to claim 2, wherein
the nozzle mechanism includes a biasing part is configured to bias the nozzle body in the radial direction relative to the support, and
the position adjuster is configured to regulate a stationary position of the nozzle body in the radial direction against biasing force from the biasing part and changes the stationary position in the radial direction.

4. The substrate processing apparatus according to claim 3, wherein
the position adjuster includes a male screw extended along the radial direction in either the nozzle body or the support, a through hole provided for the male screw to be inserted in the other, and a nut threadedly engaged with the male screw.

5. The substrate processing apparatus according to claim 4, wherein
the nozzle body includes: a columnar intermediate part having a constant sectional shape in the radial direction; a nozzle head part port connected to one end of the intermediate part in the radial direction and provided with the discharge port for discharge of the processing liquid; and a male screw part connected to the other end of the intermediate part in the radial direction and provided with the male screw,
the support is provided with a groove or a through hole as a first engagement part having a shape conforming to the sectional shape of the intermediate part,
the intermediate part is a second engagement part, and
the first engagement part and the second engagement part are slidably engaged with each other.

6. The substrate processing apparatus according to claim 5, wherein
the sectional shape of the intermediate part is a non-circular shape.

7. The substrate processing apparatus according to claim 4, wherein
scales are formed at a regular angular interval at an outer periphery of the nut.

8. The substrate processing apparatus according to claim 4, wherein
the nozzle body, the support, and the nut are composed of resin.

9. The substrate processing apparatus according to claim 3, further comprising:
a rotating cup configured to collect droplets of the processing liquid scattered from the substrate while surrounding an outer periphery of the substrate and rotating about the vertical axis during rotation of the substrate, wherein
the support is mounted on a fixing member working independently of the rotations of the substrate and the rotating cup, and
a position of mounting of the support on the fixing member is changeable.

10. The substrate processing apparatus according to claim 9, wherein
the support is a single support configured to support a plurality of the nozzle bodies.

11. The substrate processing apparatus according to claim 2, wherein
the position adjuster includes a nozzle moving mechanism configured to move the nozzle body in a nozzle moving direction that is the radial direction of the substrate or a direction tilted from the radial direction in a horizontal plane, and
the position of the discharge port in the radial direction is adjusted by moving the nozzle body in the nozzle moving direction.

12. The substrate processing apparatus according to claim 11, wherein
the nozzle moving mechanism includes:
a nozzle driver configured to drive the nozzle body in the nozzle moving direction using an actuator mounted on the support;
a guide shaft having one end coupled to the nozzle body and the other end reaching a through hole formed at the support and extending in the nozzle moving direction, the guide shaft moving in the nozzle moving direction integrally with the nozzle body; and
a pair of seal rings separated from each other in the nozzle moving direction in the through hole and fitted between an outer peripheral surface of the guide shaft and an inner peripheral surface of the through hole to seal a ring-shaped space between the guide shaft and the through hole.

13. The substrate processing apparatus according to claim 12, wherein
each of the seal rings includes a ring-shaped slidable contact part in slidable contact along an entire perimeter with the outer peripheral surface of the guide shaft, and a ring-shaped tight contact part in tight contact along an entire perimeter with the inner peripheral surface of the through hole.

14. The substrate processing apparatus according to claim 12, wherein
the nozzle moving mechanism further includes a movable support movable in the nozzle moving direction,
the nozzle body and the one end of the guide shaft are coupled to each other via the movable support, and
the nozzle driver is configured to move the movable support, the nozzle body, and the guide shaft integrally in the nozzle moving direction by moving the movable support in the nozzle moving direction using the actuator.

15. The substrate processing apparatus according to claim 11, wherein
the support is a single support that supports a plurality of the nozzle bodies, and
the nozzle moving mechanism is provided for each of the nozzle bodies.

16. The substrate processing apparatus according to claim 11, wherein
the support is a single support that supports a plurality of the nozzle bodies, and
the nozzle moving mechanism is configured to drive the nozzle bodies integrally.

17. The substrate processing apparatus according to claim 12, further comprising:
a rotating cup configured to collect droplets of the processing liquid scattered from the substrate while surrounding an outer periphery of the substrate and rotating about the vertical axis during rotation of the substrate, wherein
the support is mounted on a fixing member working independently of the rotations of the substrate and the rotating cup while holding the actuator.
